(19) United States
(12) Patent Application Publication
(10) Pub. No.: US 2025/0132170 A1
(43) Pub. Date: Apr. 24, 2025

(54) SYSTEMS AND APPARATUS FOR CONTROLLING FLUID FLOW

(71) Applicant: Ichor Systems, Inc., Fremont, CA (US)

(72) Inventors: Philip Ryan Barros, Pleasanton, CA (US); Greg Patrick Mulligan, Milpitas, CA (US); Christopher Bryant Davis, Georgetown, TX (US); Randolph Treur, San Luis Obispo, CA (US); Gary Lei Xing, Hayward, CA (US); Todd Mark Cushman, Santa Clara, CA (US)

(73) Assignee: Ichor Systems, Inc., Fremont, CA (US)

(21) Appl. No.: 18/915,152

(22) Filed: Oct. 14, 2024

Related U.S. Application Data
(60) Provisional application No. 63/591,953, filed on Oct. 20, 2023.
(60) Provisional application No. 63/676,548, filed on Jul. 29, 2024.

(51) Int. Cl. H01L 21/67; H10N 30/20

(52) U.S. Cl. CPC H01L 21/67017; H10N 30/20

(57) ABSTRACT

Systems for processing articles are essential for semiconductor fabrication. These systems employ a variety of apparatuses for controlling flow. In one implementation, an apparatus for controlling flow may utilize a body having a flow path extending from an inlet to an outlet. A valve, a flow restrictor, and a pressure sensor are operably coupled to the flow path. The valve incorporates first and second actuators which enable control of mass flow rates of fluid flowing through the flow path.

### CROSS-REFERENCE TO RELATED APPLICATIONS

This application claims the benefit of U.S. Provisional Application 63/591,953, filed Oct. 20, 2023, and U.S. Provisional Application 63/676,548, filed Jul. 29, 2024, which are incorporated herein by reference in their entireties.

### BACKGROUND OF THE INVENTION

Mass flow control has been one of the key technologies used in semiconductor chip fabrication. Apparatuses for controlling mass flow are important for delivering known flow rates of process gases and liquids for semiconductor fabrication and other industrial processes. Such devices are used to measure and accurately control the flow of fluids for a variety of applications. In a given fabrication tool, processing systems of the fabrication tool incorporates a variety of apparatuses for controlling flow to deliver a variety of liquids and gases. As a result, efficient gas and liquid handling is essential to modern semiconductor fabrication equipment.

As the technology of chip fabrication has improved, so has the demand on the apparatuses for controlling flow. Semiconductor fabrication processes increasingly require increased performance, a greater range of flow capability, more process gases and liquids, and more compact installation of the necessary equipment. Improved gas and liquid handling for a variety of fluids is desirable, particularly enhanced performance in reduced physical space.

### SUMMARY OF THE INVENTION

The present technology is directed to systems for processing articles such as semiconductors. In other embodiments, the present technology is directed to apparatuses for controlling flows of process fluids. In yet other embodiments, the present technology is directed to methods of processing semiconductors. The present systems, apparatuses, and methods may be used in a wide range of processes such as semiconductor chip fabrication, solar panel fabrication, etc.

In one implementation, the invention is a system for processing articles. The system has a fluid supply, an apparatus for controlling flow fluidly coupled to the fluid supply, and a processing chamber fluidly coupled to an outlet of the apparatus for controlling flow. The processing chamber is configured to process semiconductor devices. The apparatus for controlling flow has a body, a valve, a flow restrictor, and a pressure sensor. The body has a flow path extending from an inlet to the outlet. The valve is operably coupled to the flow path between the inlet and the outlet, the valve configured to alter fluid flow within the flow path. The valve has a seat and a closure member. The flow restrictor has a flow impedance and is located within the flow path. The pressure sensor is configured to measure pressure within a volume between the seat of the valve and the flow restrictor.

In another implementation, the invention is an apparatus for controlling flow. The apparatus for controlling flow has a body, a valve, a flow restrictor, and a pressure sensor. The body has a flow path extending from an inlet to an outlet. The valve is operably coupled to the flow path between the inlet and the outlet, the valve configured to alter fluid flow within the flow path. The valve has a seat, a closure member, a biasing element, a first actuator, and a second actuator. The closure member is configured to engage the seat. The biasing element biases the closure member into contact with the seat. The first actuator is configured to apply a first force to the biasing element. The second actuator is configured to apply a second force to the biasing element. The flow restrictor has a flow impedance and is located within the flow path. The pressure sensor is configured to measure pressure within a volume between the seat of the valve and the flow restrictor.

In yet another implementation, the invention is an apparatus for controlling flow. The apparatus for controlling flow has a body, a valve, a flow restrictor, and a pressure sensor. The body has a flow path extending from an inlet to an outlet. The valve is operably coupled to the flow path between the inlet and the outlet, the valve configured to alter fluid flow within the flow path. The valve has a seat, a closure member, a biasing element, a first actuator, and a second actuator. The seat is located within the body. The closure member is configured to engage the seat. The biasing element biases the closure member into contact with the seat. The first actuator is configured to apply a first force to the biasing element. The second actuator is configured to apply a second force to the biasing element. The flow restrictor has a flow impedance and is located within the flow path. The pressure sensor is configured to measure pressure within a volume between the seat of the valve and the flow restrictor. The volume is less than 0.1 cubic centimeters.

In a further implementation, the invention is an apparatus for controlling flow. The apparatus for controlling flow has a body, a valve, a flow restrictor, and a pressure sensor. The body has a flow path extending from an inlet to an outlet. The valve is operably coupled to the flow path between the inlet and the outlet, the valve configured to alter fluid flow within the flow path. The valve has a seat, a closure member, a biasing element, and an actuator assembly. The closure member is configured to engage the seat. The biasing element biases the closure member into contact with the seat. The actuator assembly has a button, a plunger, a plurality of transmission pins, a piston, and a biasing element. The button engages the closure member. The plunger engages the button. The plurality of transmission pins is in contact with the plunger. The piston engages the plurality of transmission pins, and the biasing element engages the piston. The flow restrictor has a flow impedance and is located within the flow path. The pressure sensor is configured to measure pressure within a volume between the seat of the valve and the flow restrictor.

In another implementation, the invention is an apparatus for controlling flow. The apparatus for controlling flow has a body, a valve, a flow restrictor, and a pressure sensor. The body has a flow path extending from an inlet to an outlet. The valve is operably coupled to the flow path between the inlet and the outlet, the valve configured to alter fluid flow within the flow path. The valve has a seat, a closure member, a biasing element, and an actuator assembly. The closure member is configured to engage the seat. The biasing element biases the closure member into contact with the seat. The actuator assembly has a button, a piston, a housing, a second actuator, and a biasing element. The button engages the closure member. The piston engages the button and the biasing element engages the piston. The housing surrounds the piston, the housing and the piston collectively forming a first actuator. The second actuator also engages the piston. The flow restrictor has a flow impedance and is located within the flow path. The pressure sensor is configured to measure pressure within a volume between the seat of the valve and the flow restrictor.

In a further implementation, the invention is a method for processing semiconductors. In a first step, a fluid is supplied to an apparatus for controlling flow. The apparatus for controlling flow has a body, a valve, a flow restrictor, and a pressure sensor. The body has a flow path extending from an inlet to an outlet. The valve is located within the flow path and has a seat, a closure member, a biasing element biasing the closure member into contact with the seat, a first actuator configured to control a position of the closure member relative to the seat, and a second actuator configured to control the position of the closure member relative to the seat. The flow restrictor is located within the flow path. The pressure sensor is configured to sense a pressure within a volume between the seat of the valve and the flow restrictor. In this step, the valve is in a closed state preventing the fluid from flowing out of the outlet. In a second step, a command is received from a controller to flow the fluid at a predetermined flow rate. In a third step, the second actuator is transitioned to an active state to control the position of the closure member in a first operating mode, the position corresponding to the predetermined flow rate. In a fourth step, the second actuator is controlled in a second operating mode wherein the second actuator is controlled based on feedback from the pressure sensor.

In another implementation, the invention is a method for processing semiconductors. In a first step, a fluid is supplied to an apparatus for controlling flow. The apparatus for controlling flow has a body, a valve, a flow restrictor, and a pressure sensor. The body has a flow path extending from an inlet to an outlet. The valve is located within the flow path and has a seat, a closure member, an actuator configured to control a position of the closure member relative to the seat. The flow restrictor is located within the flow path. The pressure sensor is configured to sense a pressure within a volume between the seat of the valve and the flow restrictor. In this step, the valve is in a closed state preventing the fluid from flowing out of the outlet. In a second step, a command is received from a controller to flow the fluid at a predetermined flow rate. In a third step, the actuator is transitioned to an active state to control the position of the closure member in a first operating mode, the position corresponding to the predetermined flow rate. In a fourth step, the actuator is controlled in a second operating mode wherein the actuator is controlled based on feedback from the pressure sensor.

In yet another implementation, the invention is a system for processing articles. The system has a fluid supply, an apparatus for controlling flow fluidly coupled to the fluid supply, and a processing chamber fluidly coupled to an outlet of the apparatus for controlling flow. The processing chamber is configured to process semiconductor devices. The apparatus for controlling flow has a body, a valve, a flow restrictor, and a pressure sensor. The body has a flow path extending from an inlet to the outlet. The valve is operably coupled to the flow path between the inlet and the outlet, the valve configured to alter fluid flow within the flow path. The valve has a seat, a closure member, and an actuator. The valve is normally open when the actuator is in an inactive state. The flow restrictor has a flow impedance and is located within the flow path. The pressure sensor is configured to measure pressure within a volume between the seat of the valve and the flow restrictor.

In a further implementation, the invention is an apparatus for controlling flow. The apparatus has a body, a valve, a flow restrictor, and a pressure sensor. The body has a flow path extending from an inlet to an outlet. The valve is operably coupled to the flow path between the inlet and the outlet. The valve is configured to alter fluid flow within the flow path. The valve has a seat, a closure member configured to engage the seat, an actuator configured to control a distance between the closure member and the seat, and an adjustment means configured to adjust a pre-load between the closure member and the seat. The flow restrictor has a flow impedance located within the flow path. The pressure sensor is configured to measure pressure within a volume between the seat of the valve and the flow restrictor. When the valve is in a closed state, the pre-load is applied to compress the closure member against the seat. The pre-load is adjustable from a first force wherein the apparatus has a first maximum flow rate to a second force wherein the apparatus has a second maximum flow rate. The second force is greater than the first force and the second maximum flow rate is less than the first maximum flow rate.

Further areas of applicability of the present technology will become apparent from the detailed description provided hereinafter. It should be understood that the detailed description and specific examples, while indicating the preferred implementation, are intended for purposes of illustration only and are not intended to limit the scope of the technology.

### BRIEF DESCRIPTION OF THE DRAWINGS

The invention of the present disclosure will become more fully understood from the detailed description and the accompanying drawings, wherein:

FIG. 1 is a schematic of a processing system for manufacturing semiconductor devices utilizing one or more apparatuses for controlling flow.

FIG. 2 is a schematic of a mass flow controller, the mass flow controller being one of the apparatuses for controlling flow as may be utilized in the process of FIG. 1.

FIG. 3 is a schematic of an alternate configuration of a mass flow controller as may be utilized in the process of FIG. 1.

FIG. 4 is a block diagram illustrating a control system as may be utilized in the system of FIG. 1.

FIG. 5 is a block diagram illustrating another embodiment of a control system as may be utilized in the system of FIG. 1.

FIG. 6 is a perspective view of a mass flow controller as may be utilized in the system of FIG. 1.

FIG. 7 is a lower perspective view of the mass flow controller of FIG. 6.

FIG. 8 is a right side view of the mass flow controller.

FIG. 9 is a bottom view of the mass flow controller.

FIG. 10 is an exploded view of the mass flow controller.

FIG. 11 is a cross-sectional view of the mass flow controller taken along line 11-11 of FIG. 6.

FIG. 12 is a perspective view of another embodiment of a mass flow controller as may be utilized in the system of FIG. 1.

FIG. 13 is a cross-sectional view of the mass flow controller of FIG. 12, taken along line 13-13.

FIG. 14 is a perspective view of another embodiment of a mass flow controller as may be utilized in the system of FIG. 1.

FIG. 15 is a cross-sectional view of the mass flow controller of FIG. 14, taken along line 15-15.

FIG. 16 is a cross-sectional view showing an alternate implementation of the mass flow controller of FIG. 14.

FIG. 17 is a schematic cross-sectional view of a second alternate implementation of the mass flow controller of FIG. 14.

FIG. 18 is a schematic cross-sectional view of a third alternate implementation of the mass flow controller of FIG. 14.

FIG. 19 is a graph illustrating experimental test results achieved by adjusting pre-load between the seat and the closure member of the mass flow controller.

### DETAILED DESCRIPTION

The description of illustrative embodiments according to principles of the present invention is intended to be read in connection with the accompanying drawings, which are to be considered part of the entire written description. In the description of embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “left,” “right,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise. Moreover, the features and benefits of the invention are illustrated by reference to the preferred embodiments. Accordingly, the invention expressly should not be limited to such preferred embodiments illustrating some possible non-limiting combinations of features that may exist alone or in other combinations of features; the scope of the invention being defined by the claims appended hereto.

The present invention is directed to systems for processing articles, these systems having apparatuses for controlling fluid flow. In some embodiments, the apparatus may function as a mass flow controller to deliver a known mass flow of gas or liquid to a semiconductor or similar process. Semiconductor fabrication is one industry which demands high performance in control of fluid flows. As semiconductor fabrication techniques have advanced, customers have recognized the need for flow control devices with increased accuracy and repeatability in the mass of the delivered fluid flows. In addition, flow control devices have increased in complexity, utilizing more sophisticated arrangements that require delivery and removal of a variety of process fluids. The present systems enable rapid assembly and maintenance of systems for processing articles by utilizing standardized manifold configurations.

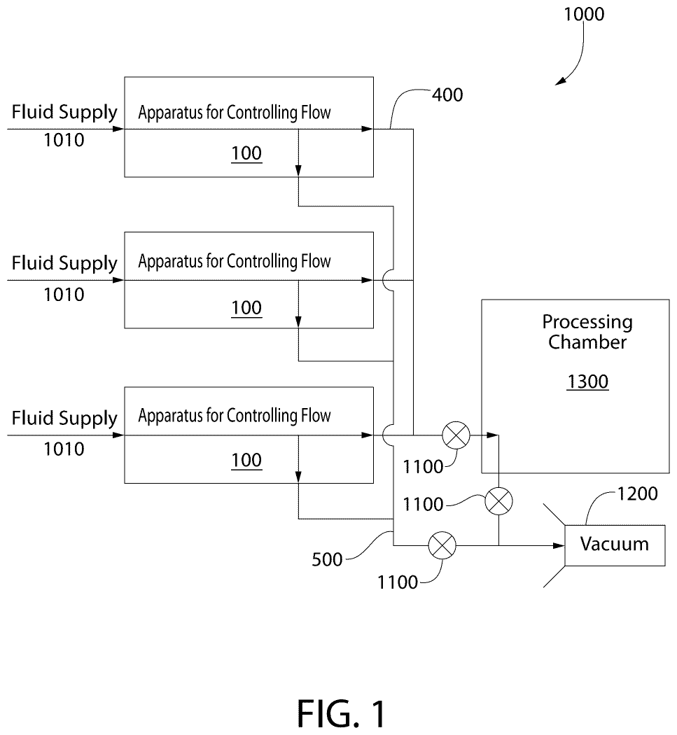

FIG. 1 shows a schematic of an exemplary processing system 1000 for processing articles. The processing system 1000 may utilize a plurality of apparatus for controlling flow 100 fluidly coupled to a processing chamber 1300. Each of the plurality of apparatus for controlling flow 100 has a fluid supply 1010 fluidly coupled thereto, each of the fluid supplies 1010 suppling a process fluid to their respective apparatuses for controlling flow 100. Optionally, a plurality of fluid supplies 1010 may be fluidly coupled to a single apparatus for controlling flow 100 or a plurality of apparatuses for controlling flow 100 may be fluidly coupled to a single fluid supply 1010. Each of the fluid supplies 1010 may deliver a different process fluid or a portion of the fluid supplies 1010 may deliver a single process fluid.

The plurality of apparatus for controlling flow 100 are used to supply one or more different process fluids to the processing chamber 1300 via an outlet manifold 400. Articles such as semiconductors may be processed within the processing chamber 1300. A valve 1100 isolates the apparatuses for controlling flow 100 from the processing chamber 1300, enabling the apparatuses for controlling flow 100 to be selectively connected or isolated from the processing chamber 1300. The processing chamber 1300 may contain one or more applicators to apply process fluids delivered by the plurality of apparatus for controlling flow 100, enabling selective or diffuse distribution of the fluid supplied by the plurality of apparatus for controlling flow 100.

In addition, the processing system 1000 may further comprise a vacuum source 1200 which is isolated from the processing chamber 1300 by a valve 1100 to enable evacuation of process fluids or facilitate purging one or more of the apparatus for controlling flow 100 to enable switching between process fluids in the same apparatus for controlling flow 100. Each of the apparatuses for controlling flow 100 may have a separate bleed port which is coupled to a vent manifold 500, the vent manifold 500 connected to the vacuum source 1200 via a valve 1100. Optionally, the apparatuses for controlling flow 100 may be mass flow controllers, flow splitters, or any other device which controls the flow of a process fluid in a processing system. Furthermore, valves 1100 may be integrated into the apparatus for controlling flow 100 if so desired. In some implementations this may eliminate the need for certain other valves 1100 in the processing system 1000.

Processes that may be performed in the processing system 1000 may include wet cleaning, photolithography, ion implantation, dry etching, atomic layer etching, wet etching, plasma ashing, rapid thermal annealing, furnace annealing, thermal oxidation, chemical vapor deposition, atomic layer deposition, physical vapor deposition, molecular beam epitaxy, laser lift-off, electrochemical deposition, chemical-mechanical polishing, wafer testing, or any other process utilizing controlled volumes of a process fluid.

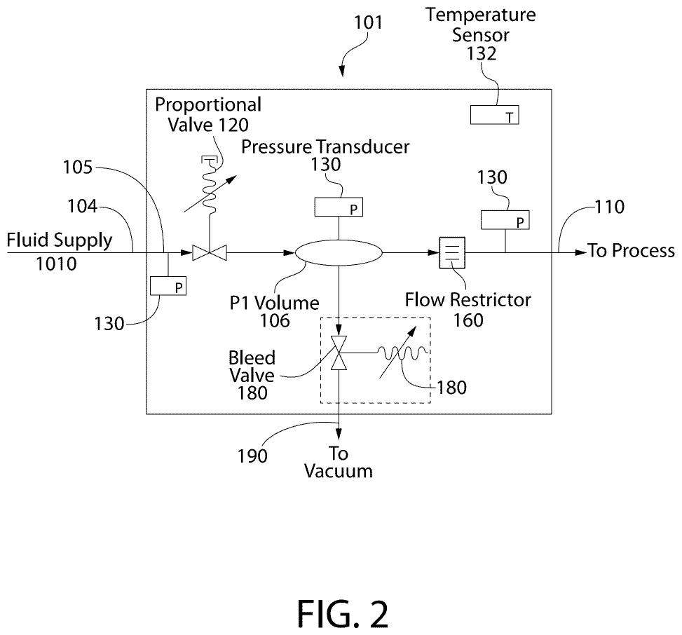

FIG. 2 shows a schematic of an exemplary mass flow controller 101, which is one type of apparatus for controlling flow 100 that may be utilized in the processing system 1000. The mass flow controller 101 has a fluid supply 1010 of a process fluid fluidly coupled to an inlet 104. A fluid pathway 105 extends from the inlet 104 to an outlet 110, the outlet 110 fluidly coupled to the outlet manifold 400. The inlet 104 is fluidly coupled to a proportional valve 120 which is capable of varying the mass and volume of process fluid flowing through the proportional valve 120. The proportional valve 120 meters the mass flow of process fluid which passes to a P1 volume 106. The proportional valve 120 is capable of providing proportional control of the process fluid such that it need not be fully open or closed, but instead may have intermediate states to permit control of the mass flow rate of process fluid.

The P1 volume 106 is fluidly coupled to the proportional valve 120, the P1 volume 106 being the sum of all the volume within the mass flow controller 101 between the proportional valve 120 and a flow restrictor 160. In particular, the P1 volume 106 is the volume between the seat of the proportional valve 120 and the flow restrictor 160 as will be discussed in greater detail below. A pressure transducer 130 is fluidly coupled to the P1 volume 106 to enable measurement of the pressure within the P1 volume 106. A second pressure transducer 130 is fluidly coupled to the outlet 110 to enable measuring the pressure differential across the flow restrictor 160.

Optionally, a shutoff valve may be used to completely halt flow of the process fluid. The shutoff valve may be located upstream, downstream, or within the mass flow controller 101. In a preferred implementation, the proportional valve 120 also serves as a shutoff valve capable of halting fluid flow. Preferably, the shutoff valve has a leakage rate across the valve seat of less than or equal to 1E-9 atm cc He/sec at room temperature, less than or equal to 1E-7 atm cc He/sec at 200 degrees Celsius or less, and less than or equal to 1E-6 atm cc He/sec at 300 degrees Celsius or less. Each of these values are for a 30 pound per square inch gauge pressure across the valve seat. The maximum allowable leak rate must be held for at least 15 seconds before Helium completely permeates through the seat material. The flow restrictor 160 is fluidly coupled to the outlet 110 of the mass flow controller 101. In the processing system, the outlet 110 is fluidly coupled to a valve 1100 or directly to the processing chamber 1300.

Finally, an optional bleed valve 180 may be coupled to the P1 volume 106 and to a bleed port 190. In the present example, the bleed valve 180 is a proportional valve. The bleed valve 180 may also be an on/off valve or any other type of valve suitable for controlling fluid flow. Optionally, a second flow restrictor 160 may be incorporated between the P1 volume and the bleed port 190. A proportional valve, if used as the bleed valve 180, enables control over a rate of fluid flow through the bleed port 190. A characterized restrictor 160 may aid in improving control over the rate of fluid flow, regardless of whether the bleed valve 180 is a proportional valve or an on/off valve. Preferably, the rate of fluid flow through the bleed valve 180 is characterized so that the flow rate can be estimated for a given state of the bleed valve 180. However, the bleed valve 180 and the bleed port 190 may be omitted as desired.

Internal to the proportional valve 120 is a valve seat and a closure member. When the apparatus 100 is delivering process fluid, the proportional valve 120 is in an open state, such that the valve seat and the closure member are not in contact. As discussed below, the open state includes all positions where the valve seat and the closure member are not in contact. The proportional valve 120 may vary the distance between the valve seat and the closure member to vary the rate of fluid flow through the proportional valve 120 or control pressure upstream or downstream of the proportional valve. When the proportional valve 120 is in a closed state the closure member and the valve seat are biased into contact by a biasing element such as a spring, stopping the flow of process fluid through the proportional valve 120. The operation of the proportional valve 120 will be discussed in greater detail below.

The flow restrictor 160 is used, in combination with the proportional valve 120, to meter flow of the process fluid. In most embodiments, the flow restrictor 160 provides a known restriction to fluid flow. The first characterized flow restrictor 160 may be selected to have a specific flow impedance to enable delivery of a desired range of mass flow rates of a given process fluid. The flow restrictor 160 has a greater resistance to flow than the passages upstream and downstream of the flow restrictor 160.

Optionally, the mass flow controller 101 comprises one or more P0 pressure transducers between the inlet 104 and the P1 volume 106. Preferably, the P0 pressure transducer, if implemented, is located between the inlet 104 and the proportional valve 120. Optionally, the mass flow controller 101 also comprises one or more P2 pressure transducers downstream of the flow restrictor 160. Preferably, the P2 pressure transducer, if implemented, is located between the outlet 110 and the flow restrictor 160. The P0, P1, and P2 pressure transducers may be used to measure the pressure differential across the flow restrictor 160 or the proportional valve 120. In some embodiments, readings of the pressure between the flow restrictor 160 and the outlet 110 may be obtained from another apparatus 100 connected to the processing chamber, with the readings communicated to the mass flow controller 101. In other embodiments, readings of the pressure between the proportional valve 120 and the inlet 104 may be obtained from another apparatus 100 connected to the fluid supply 1010.

Optionally, one or more temperature sensors 132 may be employed to further enhance the accuracy of the mass flow controller 101. They may be mounted in the base of the mass flow controller 101 near the P1 volume 106. Additional temperature sensors 132 may be employed in a variety of locations, including adjacent the proportional valve 120, the pressure transducer 130, and the bleed valve 180.

The proportional valve 120, the shutoff valve (if separately equipped), and the bleed valve 180 may be referred to as active components because they are actively controlled to achieve the desired control of fluids through the plurality of apparatus for controlling flow 100. The active components need not be valves, and may also include devices which selectively restrict flow, or otherwise alter a characteristic of the fluid flowing through the apparatus for controlling flow. Other types of active components may be flow regulators, transducers, or actuators.

The pressure transducer 130 and the temperature sensors 132 may be referred to as sensors because they detect or sense a characteristic of a fluid within a fluid pathway 105 of the plurality of apparatus for controlling flow 100. In other implementations, the pressure transducer 130 or the temperature sensor 132 may be used to sense a characteristic of a fluid within the system, but external to the plurality of apparatus for controlling flow. For example, when two apparatus for controlling flow are fluidly coupled by the outlet manifold 400, a pressure within one apparatus for controlling flow can be measured by a pressure transducer located within a second apparatus for controlling flow. Other types of sensors may include transducers, flow sensors, accelerometers, gyroscopes, or any other known device for sensing a characteristic within the system including characteristics of the fluids or characteristics of the apparatus for controlling flow 100.

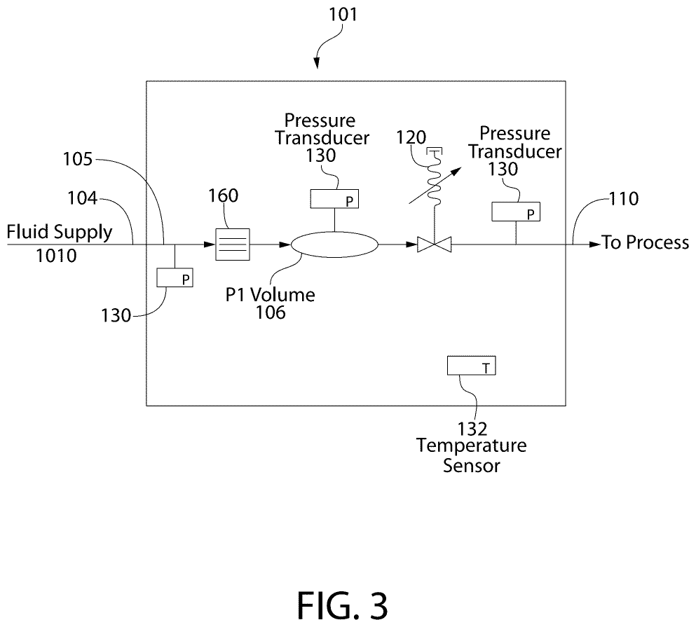

In other implementations, such as that shown in FIG. 3, the mass flow controller 101 may utilize an alternate configuration where the flow restrictor 160 is fluidly coupled to the inlet 104, the inlet 104 fluidly coupled to the fluid supply 1010. The flow restrictor 160 is fluidly coupled to the proportional valve 120, with the P1 volume 106 located between the flow restrictor 160 and the seat of the proportional valve 120. A first pressure transducer 130 is fluidly coupled to the fluid supply 1010. A second pressure transducer 130 is fluidly coupled to the P1 volume 106 so that it senses pressure within the P1 volume 106. A third pressure transducer 130 serves as a P2 pressure transducer to sense pressure between the proportional valve 120 and the outlet 110. As noted above, the proportional valve 120 may function as an on/off valve or separate on/off valve may be fitted to the mass flow controller 101. In yet further configurations, an on/off valve may be located upstream or downstream of the mass flow controller 101.

Optionally, a bleed valve 180 may be included or omitted in the mass flow controller 101 of FIG. 3. Further optionally, the first and third pressure transducers 130 may be omitted or located elsewhere. The proportional valve 120 may be substituted with an on/off valve, and the location of the proportional valve 120 and the flow restrictor 160 may be switched. In yet other implementations, the valve 1100 may be used in place of the on/off valve 150.

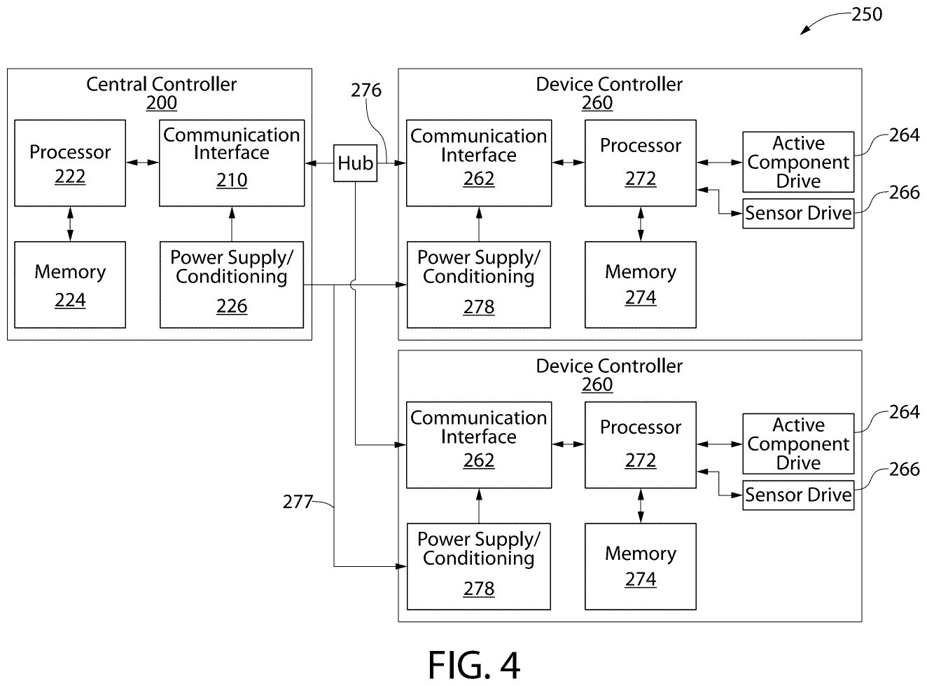

Turning to FIG. 4, a block diagram illustrates a controller 250 for the processing system 1000 of FIG. 1. This block diagram shows a device controller 260 and a central controller 200. The device controller 260 provides interface functions for an apparatus for controlling flow 100 within the processing system 1000 and enables control of the apparatus for controlling flow 100. The device controller 260 has a communication module 262, at least one active component drive 264, at least one sensor drive 266, a processor 272, memory 274, and a power supply/conditioning module 278.

Optionally, a single device controller 260 may operate a plurality of apparatuses for controlling flow 100 or each apparatus for controlling flow 100 may have a dedicated device controller 260, each of the device controllers 260 communicating with the central controller 200 and other apparatus controllers 260 via a communication bus 276. The communication module 262 is configured to provide a communications link between the apparatus controller 260 and the central controller 200. The communication module 262 may be configured to communicate with the central controller 200 and other device controllers 260 via the communication bus 276 as will be discussed in greater detail below.

The device controller 260 may utilize one or more active component drives 264 to enable control of active components such as the proportional valve 120, bleed valve 180, and on/off valve 150. The active component drives 264 may be valve drives or any other type of drive required to operate solenoids, piezoelectric devices, or other devices required to operate the active components. The active component drives 264 may enable proportional control or on/off control of valves or other active devices as desired. In some implementations, the active component drives 264 may be dedicated to specific types of active components or may be configured to be used with a variety of different types of active components.

The device controller 260 may also utilize one or more sensor drives 266, the sensor drives 266 configured to interface with the sensors of the apparatus for controlling flow 100. For example, the sensor drives 266 may be configured to generate sensor data from pressure transducers 130 or temperature sensors 132 of the mass flow controller 101. The sensor drives 266 may generate sensor data as analog data or may generate sensor data in a digital format. The sensor drives 266 may be configured for specific sensor types or may be configured to interface with a variety of different sensor types. For example, the device controller 260 may implement a single type of sensor drive 266 which can interface with both temperature sensors 132 and pressure transducers 130. Alternately, the device controller 260 may have dedicated sensor drives 266 for each type of sensor.

The processor 272 and the memory 274 of the device controller 260 may interface with the communication module 262, the sensor drive 266, and the active component drive 264. The memory 274 may store calibration data for the mass flow controller 101 or other apparatus for controlling flow 100, including the sensors and the active components. The memory 274 may further store setpoints for the mass flow controller 101 or other apparatus for controlling flow 100. In other configurations as will be discussed further below, the setpoints may be stored in other locations. The processor 272 may implement a control loop which relies on sensor data from the sensor drives 266 to control the active components of the mass flow controller 101 or other apparatus for controlling flow 100 via the active component drives 264. In other implementations, the control loop may be implemented external to the device controller 260.

The central controller 200 has a communication module 210, a processor 222, a memory 224, and a power supply/conditioning module 226. The central controller 200 coordinates functions necessary to perform desired processes on the semiconductor devices or other articles to be processed. The communication module 210 of the system controller 200 sends and receives commands through the communication bus 276. The communication bus 276 connects to the communication module 262 of one or more device controllers 260 operating one or more apparatus for controlling flow 100. The communication bus 276 may connect the central controller 200 to a single device controller 260, or it may connect to a plurality of device controllers 260. Each device controller 260 may operate a distinct apparatus for controlling flow 100 or a plurality of apparatus for controlling flow. In yet other implementations, some device controllers 260 may not control an apparatus for controlling gas flow 100. Instead, other types of process equipment may also be controlled by the device controller 101. Optionally, the communication bus 276 may incorporate a hub or other device which enables connection of all apparatus for controlling flow 100 required to complete a desired set of processes on an article to be processed. Furthermore, there may be a plurality of communication buses 276 to connect all the devices required to perform the desired process. In other implementations, the communication bus 276 may be substituted with a plurality of direct communications links between individual controllers 200, 260.

The communication bus 276 may be a serial bus, a parallel bus, or a combination of serial and parallel bus. Thus, the communication bus 276 may enable communication via one of a variety of protocols including serial communication protocols or parallel communication protocols. For example, the communication modules 210, 262 may transmit messages or other data packets using any one of a variety of protocols. For example, data may be transmitted as sensor data messages and active component messages, with the sensor data messages containing sensor data and the active component messages containing active component commands. Other types of messages such as setpoint messages may be transmitted via the communication bus 276, the setpoint messages containing desired setpoints for the apparatus for controlling flow 100. A variety of protocols may be used, including protocols using RS-232, RS-422, RS-485 or other standards. Other protocols may include Ethernet, EtherCAT, Modbus, Profibus, Profinet, DeviceNet, CANbus, Fieldbus, OPC, MQTT, BACnet, or any other known communications protocol or standard to enable communications between the central controller 200 and the device controllers 260.

A power connection 277 may be implemented, with the central controller 200 providing power from the power supply/conditioning module 226 of the central controller 200 to the power supply/conditioning modules 278 of the device controllers 260 via the power connection 277. In some implementations, the power connection 277 may be incorporated into the communication bus 276. In other implementations, power connections 277 may be provided from the central controller 200 to the device controllers 260 separately from the communication bus 276. Optionally, power may be transmitted over the communication bus 276 in a manner analogous to power over ethernet (“POE”) type systems where the communication bus is also a power bus.

The central controller 200 may be coupled to mains power, with the power supply/conditioning module 226 converting mains power to 12 to 24 volts DC. The power supply/conditioning modules 278 of the device controllers 260 may convert the supplied 12 to 24 volts DC from the power supply/conditioning module 226 to 3.3 volts, 5 volts, or 12 volts DC for direct use by device controller 260. The power supply/conditioning module 226 may also supply 3.3 volts, 5 volts, or 12 volts DC for use by the central controller 200. In other implementations, each of the device controllers 260 may be directly connected to mains power and the power supply/conditioning modules 278 may convert mains power directly to the required voltage levels for the device controllers 260.

The processor 222 and the memory 224 implement the desired processes on the articles to be processed, storing parameters and executing stored instructions required to operate the system 1000. For example, the memory 224 may store setpoints for a plurality of apparatus for controlling flow 100 and the processor may use the communication module 210 to transmit setpoint messages to the device controllers 260, the device controllers 260 controlling their active components based on sensor data from their sensors and setpoint data within the setpoint messages. Thus, a control loop may be implemented within the device controllers 260. Optionally, sensor data from other device controllers 260 of other apparatus for controlling flow 100 may also be used to control the active components. Thus, control of fluids may be achieved. For example, the system may deliver desired mass flow rates of gas or liquid at desired times and for desired durations as commanded by the central controller 200. The device controllers 260 may implement any required feedback control loops to control the active controllers.

In other implementations, the central controller 200 may store setpoint information in the memory 224 and the processor 222 may implement the required feedback control loops for all apparatus for controlling flow 100. Thus, sensor data messages from each of the device controllers 260 of the apparatus for controlling flow 100 may be transmitted to the central controller 200. Sensor data from the sensor data messages may be used, in combination with the setpoints stored in the memory 224, to compute active component commands and transmit active component messages to the device controllers 260. The device controllers 260 may then cause the active components to be controlled in accordance with the active component commands, new sensor data can be transmitted back to the central controller 200, and the active component commands can be recomputed and retransmitted to the device controllers 260. Thus, the feedback loop may be implemented in the central controller. It is further contemplated that some apparatus for controlling flow 100 may exclusively generate sensor data while other apparatus for controlling flow may exclusively incorporate active components, with sensor data from a first apparatus for controlling flow used to control an active component in a second apparatus for controlling flow. In yet other configurations, sensor data from a first and second apparatus for controlling flow may be used to compute the active component command for the first apparatus for controlling flow.

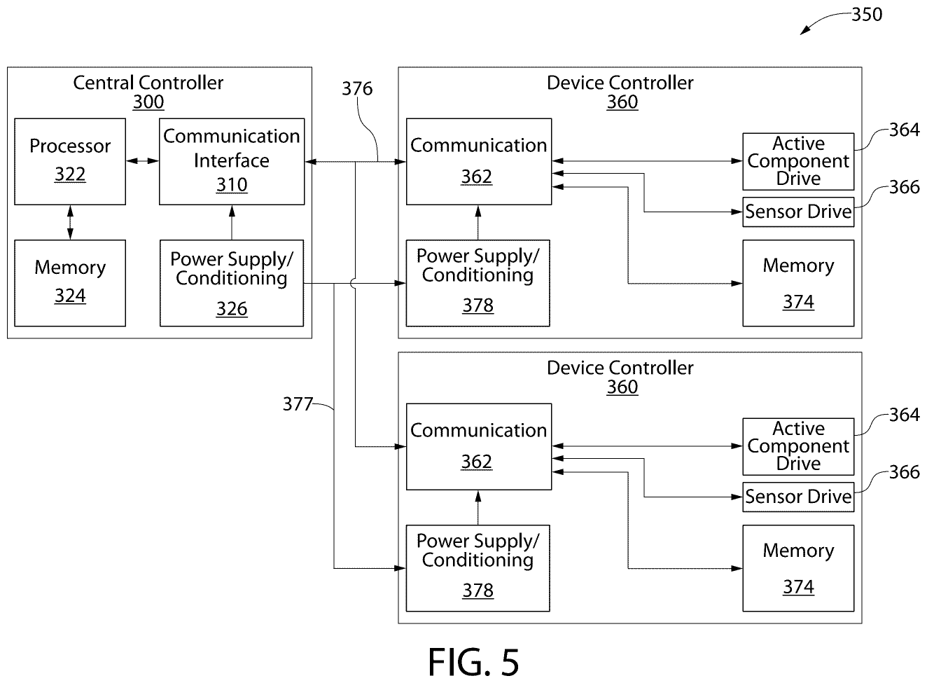

Turning to FIG. 5, another controller 350 having a central controller 300 and a plurality of device controllers 360 is illustrated. The central controller 300 has a processor 322, a memory 324, a communication module 310, and a power supply/conditioning module 326. A communication bus 376 and a power connection 377 link the central controller 300 to the plurality of device controllers 360. Optionally, each of the device controllers 360 may not implement a processor. The device controllers 360 may have a communication module 362, a memory 374, an active component drive 364, a sensor drive 366, and a power supply/conditioning module 378. Thus, sensor data is passed directly from the sensor drive 366 to the communication module 362. Similarly, active component commands are passed directly from the communication module 362 to the active component drive 364. As above, it is contemplated that sensor data from different apparatus for controlling flow 100 may be combined to compute the active component command for a single apparatus for controlling flow 100, and that not all apparatus for controlling flow 100 may incorporate both a sensor and an active component. Calibration values for the sensors and active components may be stored in the memory 374.

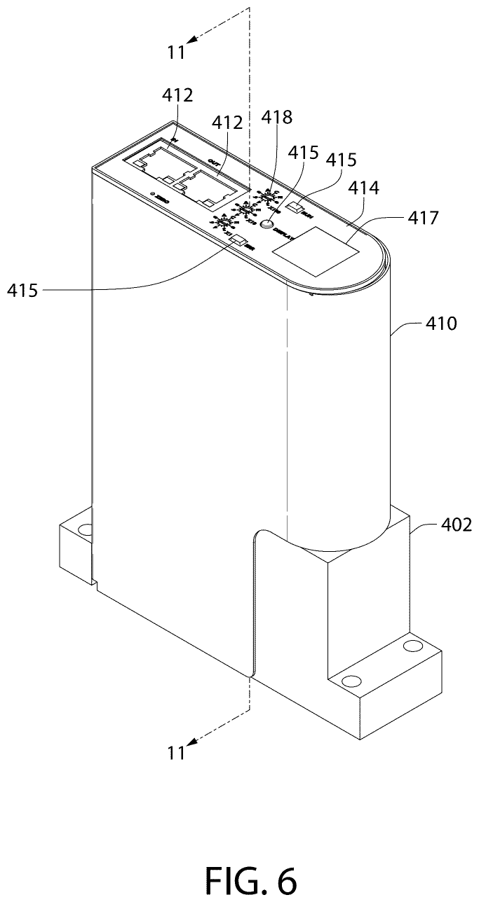

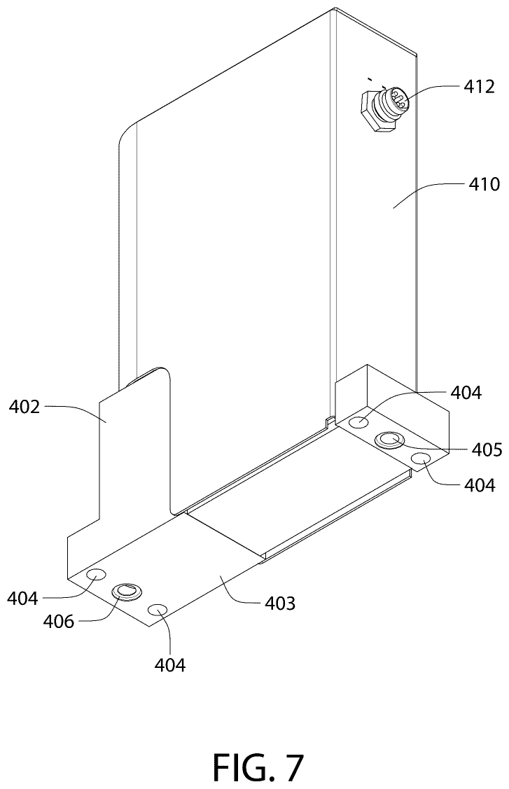

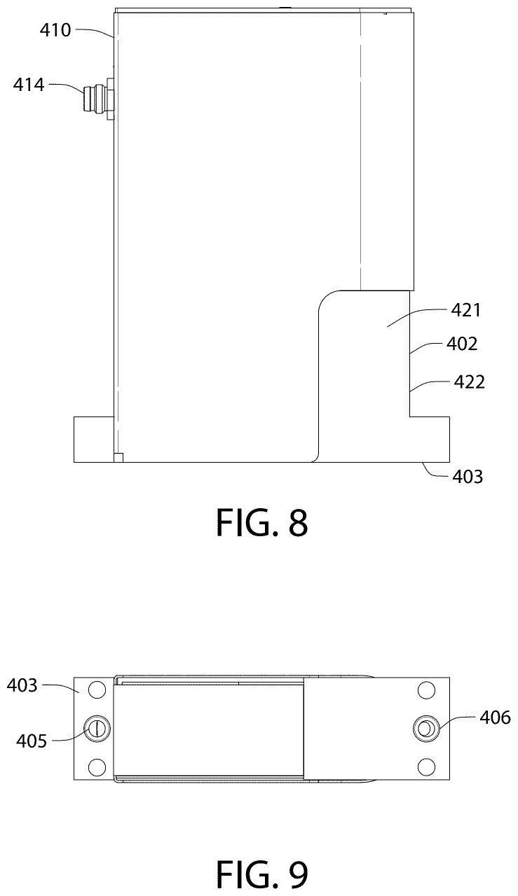

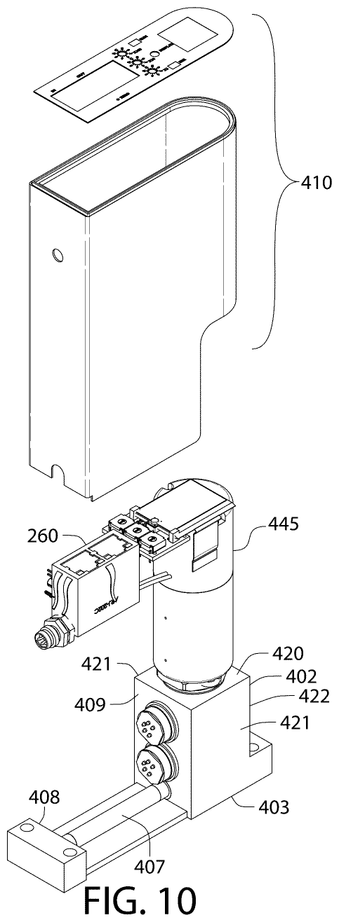

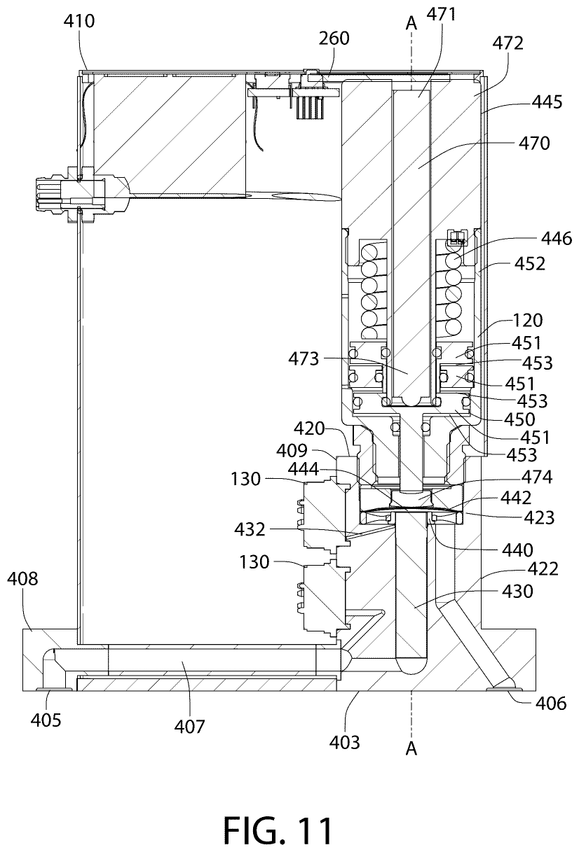

FIGS. 6-11 illustrate a mass flow controller 401 which is one of the potential apparatuses for controlling flow 100 that may be used in the processing system 1000. The mass flow controller 401 has a body 402 which receives one or more components. A housing 410 is coupled to the body 402, the housing covering the components which are mounted to the body 402. The housing 410 may have provisions for one or more connectors 412 and a user interface 414. Preferably, the housing 410 is formed of sheet metal and is detachably coupled to the body 402 to allow servicing of the mass flow controller 401. The user interface 414 may include buttons 415, indicators, a display 417, and one or more variable input devices 418 such as potentiometers or encoders.

The body 402 may incorporate a mounting surface 403 and a plurality of mounting apertures 404 configured to allow mounting of the body 402 to a substrate component, fluid fitting, substrate, or other component. The mounting apertures 404 may permit the passage of fasteners such as bolts or may be formed in other shapes suitable to receive clips or other known fasteners. The mounting surface 403 has an inlet 405 and an outlet 406 formed therein. A flow path 407 for fluid extends from the inlet 405 to the outlet 406. Optionally, the body 402 may include a first extension 408, the inlet 405 formed in the first extension 408. The first extension 408 includes a portion of the flow path 407, the first extension 408 forming a portion of the mounting surface 403.

The inlet 405 and outlet 406 may incorporate seal cavities to receive seals or may be configured to allow welding or adhesive attachment of fittings or other components instead of seal cavities. In addition, the inlet 405 and the outlet 406 may not be formed into the mounting surface 403, instead being formed into another surface of the body 402, particularly where fittings are used instead of seal cavities.

The body 402 further incorporates an interior surface 409, a top surface 420, side surfaces 421, and a rear surface 422. Optionally, the interior surface 409 or the side surfaces 421 may receive one or more pressure sensors 130 or temperature sensors 132. The top surface 420 may incorporate a cavity 423 which receives the valve 120. The cavity 423 may receive various components of the valve 120 as will be discussed below. A flow restrictor 430 may also be at least partially located within the cavity 423, the flow restrictor 430 located within the flow path 407 and immediately adjacent the seat 440 of the valve 120. The flow restrictor 430 provides a flow impedance to fluid flow.

The mass flow controller 401 also incorporates the device controller 260 as discussed above. The device controller 260 may be located within the housing 410 and includes all electrical components, connectors, and other components required to interface with the central controller 200 and operate the valve 120, pressure and temperature sensors 130, 132, and other devices within the mass flow controller 401.

In the mass flow controller 401, the flow restrictor 430 is located between the seat 440 of the valve 120 and the inlet 405 along the flow path 407. The valve 120 is located between the flow restrictor 430 and the outlet 406 along the flow path 407. However, the location of the valve 120 and the flow restrictor 430 may be reversed in other implementations as noted above.

The valve 120 further incorporates a closure member 442 which engages the seat 440. The closure member 442 may be a diaphragm or other element which prevents fluid flow when it is engaged with the seat 440. Thus, the valve 120 is configured to alter fluid flow within the flow path 407. The valve 120 may be a proportional valve capable of varying fluid flow. The valve 120 may also function as an on/off valve which completely halts the flow of fluid through the flow path 407. Flow through the valve 120 increases with increasing distance between the closure member 442 and the seat 440, and the distance may be varied to achieve the desired flow rate.

A first one of the pressure sensors 130 is fluidly coupled to the flow path 407 between the flow restrictor 430 and the inlet 405, allowing the pressure sensor 130 to sample the pressure of the fluid at the inlet 405. A second one of the pressure sensors 130 is fluidly coupled to a volume 444 defined between the seat 440 and the flow restrictor 430. A fluid connection path 432 is provided between the second one of the pressure sensors 130 coupled to the body 402 and the volume 444. The fluid connection path 432 is partially formed into the body 402 and partially formed by a groove in the flow restrictor 430, allowing fluid communication between the pressure sensor 130 and the volume 444 while minimizing the packaging size and the additional volume required to monitor pressure within the volume 444. The volume 444 is defined by the flow restrictor 430 and the portion of the flow path 407 extending to a surface of the seat 440 that is engaged by the closure member 442. Preferably, the volume 444 is less than 0.1 cubic centimeters. Further preferably, the volume 444 is less than 0.01 cubic centimeters.

Returning to the valve 120, a biasing element 446 provides a biasing force which biases the diaphragm into a normally closed position where the diaphragm 442 is in contact with the seat 440. The biasing force ends generally along a longitudinal axis A-A that extends through the seat 440. This causes the valve 120 to be in a closed state. The valve 120 further includes a first actuator 450 and a second actuator 470 that collectively form an actuator assembly 445. The first actuator 450 may be a pneumatic actuator, hydraulic actuator, motor and screw actuator, solenoid, linear motor, or other known type of actuator. The second actuator 470 may be a piezoelectric actuator, motor and screw actuator, linear motor, solenoid, or other known type of actuator.

Preferably, the first actuator 450 is a pneumatic actuator comprising one or more pistons 451 within a housing 452 of the valve 120. The pistons 451 and the housing 452 collectively form one or more chambers 453. The chambers 453 may be pressurized to apply a first force in a direction opposite the biasing force along the longitudinal axis A-A. The first force may be greater than the biasing force, causing the diaphragm 442 to be separated from the seat 440 by a first distance. The first force may be sufficient to move the pistons 451 against mechanical stops, limiting further upward travel away from the valve seat 440. Thus, placing the first actuator 450 in an active state transitions the valve 120 from the closed state to an open state, the open state occurring as soon as the closure member 442 is separated from the valve seat 440 by a non-zero distance.

The second actuator 470 is preferably a piezoelectric actuator or other actuator having a faster response time than the first actuator 450. The second actuator 470 is arranged in a generally cylindrical configuration, with a first end 471 coupled to a cap element 472 forming a part of the housing 452. The first end 471 may engage the cap element 472 via threads or may be contained within the cap element 472, providing a fixed end or travel limit for the second actuator 470. Extension of the second actuator 470 causes a second end 473 to move downward along the longitudinal axis A-A toward the valve seat 440. Thus, the second actuator 470 applies a second force which is in the same direction as the biasing force. The second actuator 470, when in an active state, causes the closure member 442 to move toward the seat 440. The second end 473 engages one of the pistons 451, which in turn engages a button 474 which engages the closure member 442. The second actuator 470 is placed in the active state by applying a drive voltage, with increasing drive voltages increasing the extension of the second actuator.

As can be seen, placing the second actuator 470 in an active state while the first actuator 450 is in an active state causes the distance between the closure member 442 and the seat 440 to be reduced. Placing the second actuator 470 in the active state while the first actuator 450 is in an inactive state will simply increase the compression force of the closure member 442 against the seat 440 and the distance will be zero. Placing the second actuator 470 in an inactive state while the first actuator 450 is in an active state will allow the distance between the closure member 442 and the seat 440 to be maximized, maximizing fluid flow.

During operation of the mass flow controller 401, the valve 120 may be controlled in two operating modes. Prior to operating in a first operating mode, the valve 120 is in a closed state and no fluid flows through the outlet 406. Upon receipt of a command to flow fluid at a predetermined flow rate, the valve 120 is transitioned to the open state. This is done by transitioning the first and second actuators 450, 470 to an active state. The position of the closure member 442 relative to the seat is then controlled based on position feedback provided by a position feedback sensor. The position feedback sensor may be a strain gauge, capacitive sensor, or any other known position feedback sensor. The position feedback sensor may be provided as a part of the second actuator 470 or separately installed in the valve 120.

In the first operating mode, the second actuator 470 is controlled based on position information provided by the position feedback sensor, but no feedback is provided with respect to the flow rate of fluid provided by the mass flow controller 401. The position of the closure member 442 of the valve 120 is determined based on a table, database, or formula which correlates the position to the desired mass flow rate. This table, database, or formula may be stored in the memory of either the central controller 200 or the device controller 260.

The first operating mode does not rely on feedback of the delivered mass flow rate to set the commanded position and operates in an open loop control mode. While there is position feedback to control the position of the closure member 442, there is no feedback for the mass flow rate of the fluid as mentioned above. Otherwise stated, the predetermined flow rate corresponds to a position setpoint, the position of the closure member 442 of the valve 120 driven to the position setpoint.

After a period of time, the valve 120 is transitioned to a second operating mode where the second actuator 470 is controlled based on feedback from the pressure sensor 130 which monitors pressure within the volume 444. The period of time may be predetermined or based on other factors. Optionally, feedback from the temperature sensor 132 and the first pressure sensor 130 which monitors pressure at the inlet 405 is also used to calculate the mass flow rate. The position of the closure member 442 is then adjusted based on feedback from the pressure sensor 130 to deliver the desired mass flow rate. Preferably, the valve 120 is controlled in the second operating mode once the fluid flow has approached steady state, avoiding control fluctuations resulting from fluctuations in the measured pressure of the fluid within the volume 444. When transitioning to the first operating mode, the first actuator 450 may be transitioned to the active state simultaneously with the second actuator 470, or the first actuator 450 may be transitioned to the active state before the second actuator 470 is transitioned to the active state.

In one implementation, the valve 120 is transitioned to the second operating mode when the pressure within the volume 106 stabilizes within a predetermined range. For example, the pressure may stabilize within 5 percent of a target pressure corresponding to the desired mass flow rate of the fluid being dispensed. Thus, instead of using a predetermined period of time, the time may be based on reaching a stable pressure measurement within the volume 106.

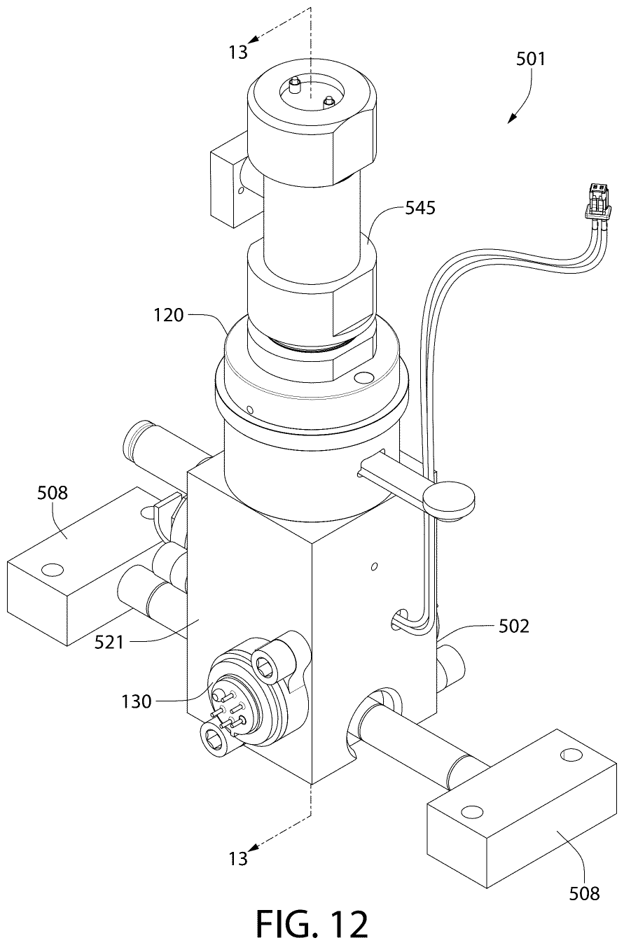

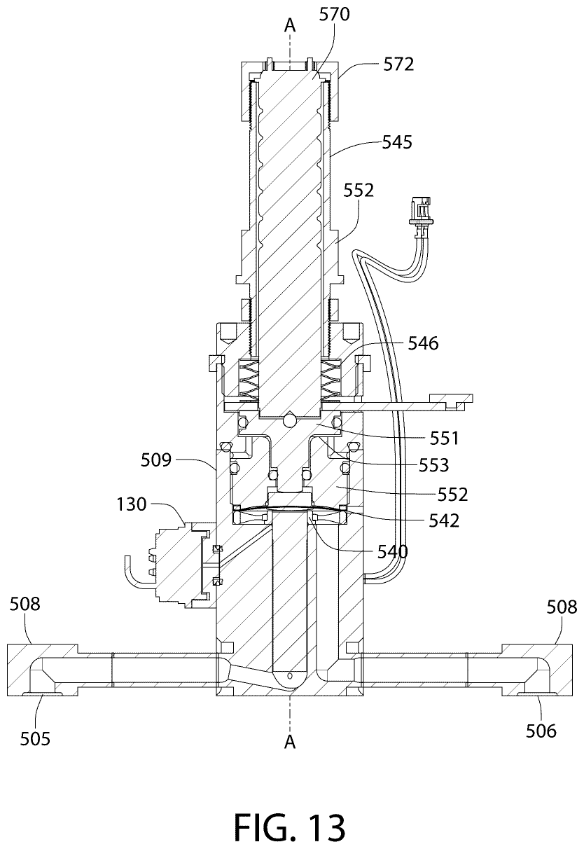

Turning to FIGS. 12 and 13, another embodiment of a mass flow controller 501 is illustrated. The mass flow controller 501 also incorporates a base 502 having first and second extensions 508, with each of the extensions 508 housing one of the inlet 505 and outlet 506. The pressure sensors 130 are mounted to an interior surface 509 and a side surface 521 of the base 502.

The mass flow controller 501 incorporates a valve 120 similar to the valve 120 used in the mass flow controller 401. The valve 120 has a first actuator 550 and a second actuator 570 which collectively form an actuator assembly 545. The first actuator 550 is a pneumatic actuator formed of a piston 551 and housing 552. The piston 551 and housing 552 form a chamber 553 which may be pressurized to apply a first force counter to a biasing force applied by a biasing element 546. The second actuator 570 may be a piezoelectric actuator which is secured by a cap element 572, the cap element 572 threadedly secured to the housing 552 to allow adjustment of the positioning of the second actuator 570 within the housing 552.

The first and second actuators 550, 570 apply first and second forces along a longitudinal axis A-A. The first force of the first actuator 550 counteracts the biasing force of the biasing element 546 because the first force is directed opposite the biasing force. The second force supplements the biasing force and is directed in the same direction as the biasing force. Thus, the position of the closure member 542 relative to the valve seat 540 is controlled by modulation of the second force once the first force is applied by transitioning the first actuator 550 into the active state.

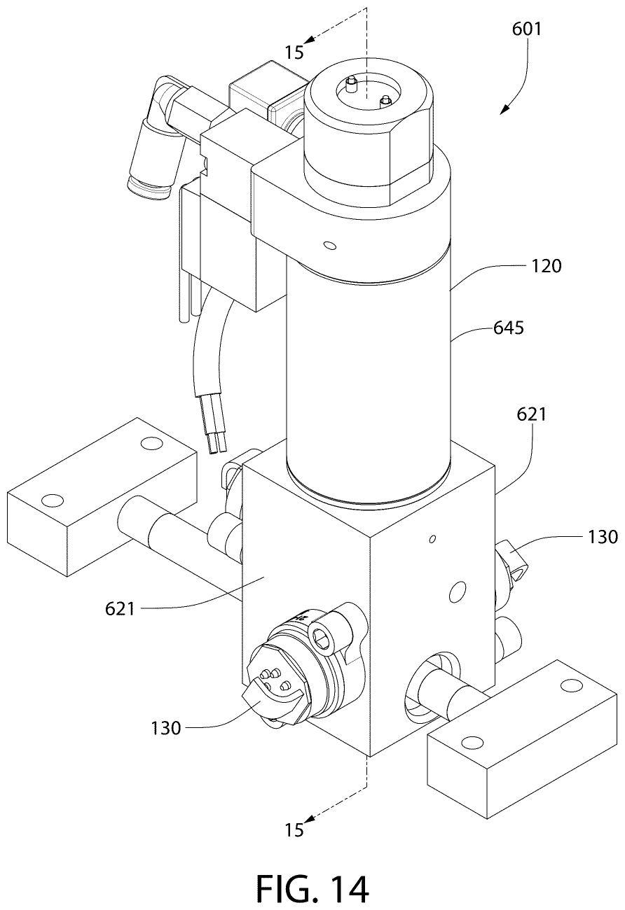

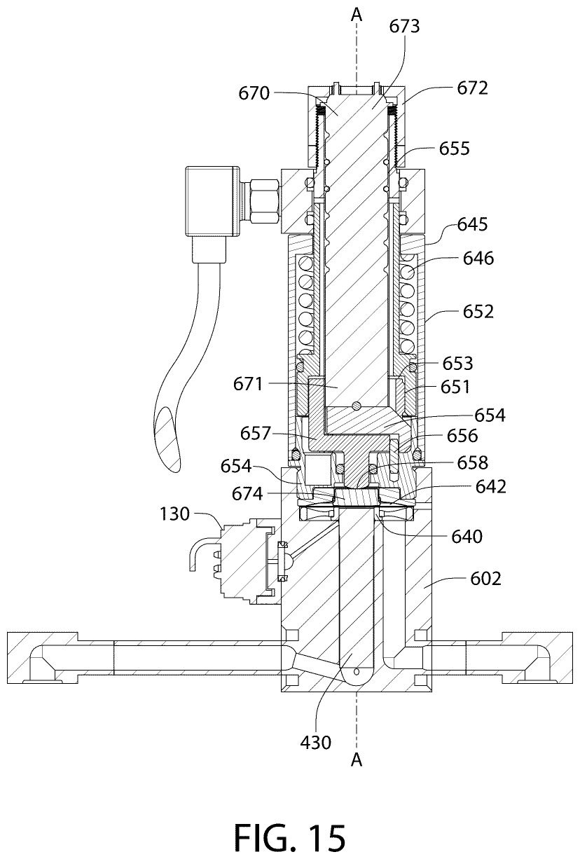

FIGS. 14 and 15 illustrate another embodiment of the mass flow controller 601. The mass flow controller 601 incorporates a valve 120 mounted on a body 602, with first and second pressure sensors 130 mounted to opposite side surfaces 621 of the body 602. The valve 120 has a first actuator 650 formed by a piston 651 and a housing 652. A chamber 653 is formed between the piston 651 and the housing 652. The housing 652 is coupled to a base element 654, the base element 654 fixedly coupled to the body 602 and the housing 652. The first actuator 650 is configured to apply a first force along a longitudinal axis A-A which counteracts the biasing force provided by a biasing element 646 which biases the valve 120 into a normally closed position. The first force may be insufficient to separate a closure member 642 from a seat 640 of the valve 120. However, the first force reduces the contact force between the closure member 642 and the seat 640.

A cap element 672 secures a second actuator 670 within a cavity 655 of the piston 651. The second actuator 670 may be a piezoelectric actuator. The first and second actuators 650, 670 collectively form an actuator assembly 645. The second actuator 670 and the piston 651 are preferably concentric with a longitudinal axis A-A extending through the seat 640 of the valve 120. The second actuator 670 engages the base element 654 at a first end 671 of the second actuator 670 such that a second end 673 of the second actuator 670 extends upwardly away from the seat 640 when the second actuator 670 is put into an active state. This lifts the piston 651 away from the seat 640, applying a second force which counteracts the biasing force from a biasing element 646. The second force may be sufficient to separate the closure member 642 from the seat 640 regardless of whether the first actuator 650 is active and the first force is present.

The piston 651 is coupled to the closure member 642 via transmission pins 656, the transmission pins 656 extending through the base element 654 to a plunger 657. The plunger 657 engages a button 674, the button 674 engaging the closure member 642. When the piston 651 lifts upward away from the seat 640 as a result of the first and second forces, the closure member 642 lifts from the seat due to forces applied by the fluid or by the closure member 642. The button 674, plunger 657, and the transmission pins 656 are lifted by the closure member 642 and the transmission pins 656 remain in contact with the piston 651. Optionally, the plunger 657 of the button 674 may incorporate a protuberance 658 to allow pivoting of the button 674 with respect to the plunger 657, ensuring that the closure member 642 engages the seat 640 evenly and without twisting or other uneven applications of force.

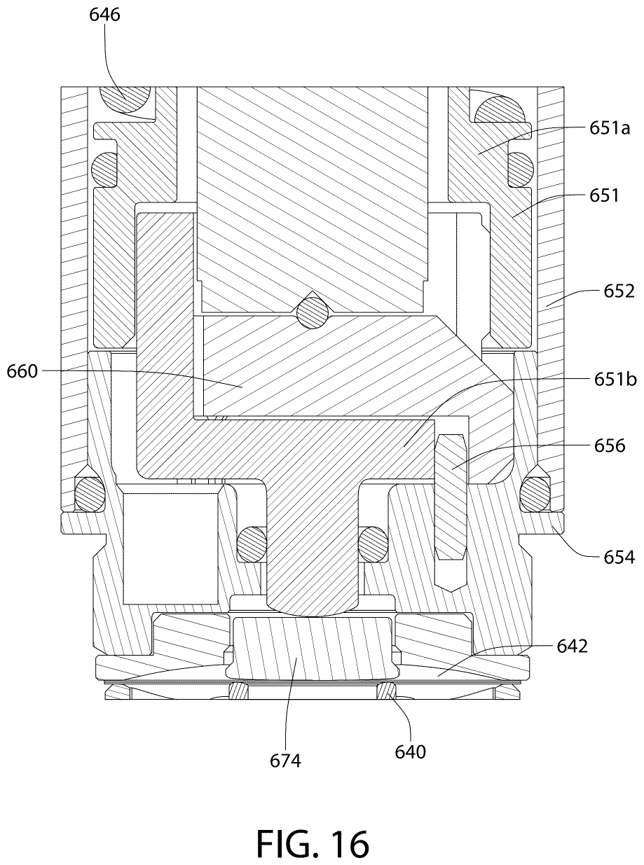

FIG. 16 illustrates an alternate configuration of the mass flow controller 601. In this configuration the piston 651 is formed in two parts, with an upper portion 651a being threadedly coupled to a lower portion 651b. The first actuator 650 is formed by the piston 651, the housing 652, and the base element 654. A chamber 653 is formed between the piston 651, the housing 652, and the base element 654. The geometry of the piston 651, housing 652, and base element 654 are configured to maximize the area available for generating the first force. Optionally, the base element 654 may be formed in multiple parts if so desired.

The piston 651 extends through the base element 654 to engage the button 674, the button 674 engaging the closure member 642. The closure member 642 engages the seat 640 to prevent fluid flow. The piston 651 is biased by the biasing force provided by the biasing element 646, the first actuator 650 configured to provide the first force in a direction opposite the biasing force. In some implementations, the first force may not be sufficient to separate the closure member 642 from the seat 640. The second actuator 670 engages a support member 660, the support member 660 coupled to the base element 654 via transmission pins 656 which extend through the lower portion 651b of the piston 651. The support member 660 may alternately be aligned by the transmission pins 656 and the support member 660 may directly engage the base element 654. The base element 654 is rigidly coupled to the body 602, so the second actuator 670 is rigidly coupled to the body 602. As with the configuration of FIGS. 14 and 15, the second actuator lifts the piston 651 and provides a second biasing force which separates the closure member 642 from the seat 640. Optionally, only the second actuator 670 may be used to put the valve 120 in the open state.

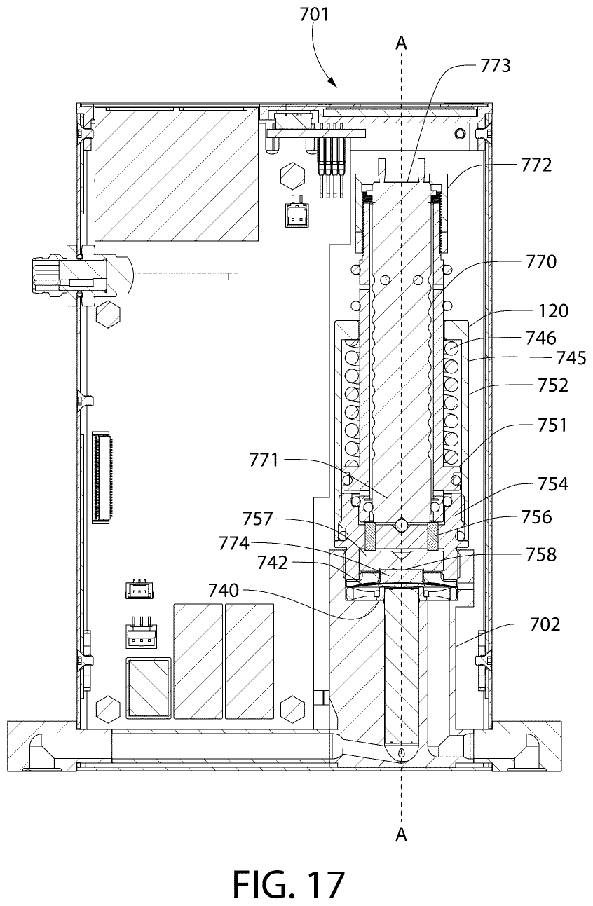

FIG. 17 illustrates another embodiment of the mass flow controller 701. The mass flow controller 701 incorporates a valve 120 mounted on a body 702. The mass flow controller 701 is substantially identical to the mass flow controllers discussed above, except for those features described herein. The valve 120 has an actuator 770 located within a housing 752, the actuator 770 and the housing 752 collectively forming an actuator assembly 745. The housing 752 may surround the actuator 770. The actuator 770 may be a piezoelectric actuator. Optionally, another actuator may be incorporated into the actuator assembly as desired, or the actuator assembly may only utilize a single actuator 770 to operate the valve 120. The valve 120 is a normally closed valve, wherein the valve 120 does not allow fluid flow when the actuator 770 is in an inactive state.

The actuator assembly 745 further comprises a biasing element 746 which biases a closure member 742 into contact with a seat 740 via a button 774. The button 774 engages the closure member 742, the button 774 operated on by a plunger 757 having a protuberance 758 to enable rotation of the button 774 relative to the plunger 757. Transmission pins 756 extend through a base element 754 to engage a piston 751, the piston 751 compressed by the biasing element 746. The piston 751 may be surrounded by the housing 752. The piston 751 mates with a cap element 772, the cap element 772 being an adjustment means which permits adjustment of a pre-load force applied between the seat 740 and the closure member 742 when the valve 120 is in a closed state. The cap element 772 may also allow adjustment of the position of the actuator 770 relative to the housing 752 and the seat 740.

The cap element 772 receives a second end 773 of the actuator 770 and transfers force from the actuator 770 to the closure member 742 via the button 774, transmission pins 756, and piston 751 to allow movement of the closure member 742 relative to the seat 740. Optionally, this force is applied along a longitudinal axis A-A to separate the closure member 742 from the seat 740. The biasing element 746 applies a biasing force against the piston 751 to bias the closure member 742 into contact with the seat 740. This causes the valve 120 to be a normally closed valve when the actuator 770 is in an inactive state.

The biasing element 746 is located between the piston 751 and the housing 752, the housing 752 coupled to the base element 754, which in turn engages a body 702 of the valve 120, the housing 752 being substantially fixed relative to the seat 740. Thus, the piston 751 may move relative to the seat 740 when the actuator 770 is placed into an active state, allowing the closure member 742 to be separated from the seat 740 by a distance. The actuator 770 has a first end 771 which is supported by the base element 754, the first end 771 also substantially fixed relative to the seat 740.

Optionally, a chamber may be formed between the piston 751 and the base element 754, allowing the formation of a second actuator as discussed above. This actuator may be used in the same manner as with other embodiments. However, this is an optional implementation, and only one actuator need be used to operate the valve 120.

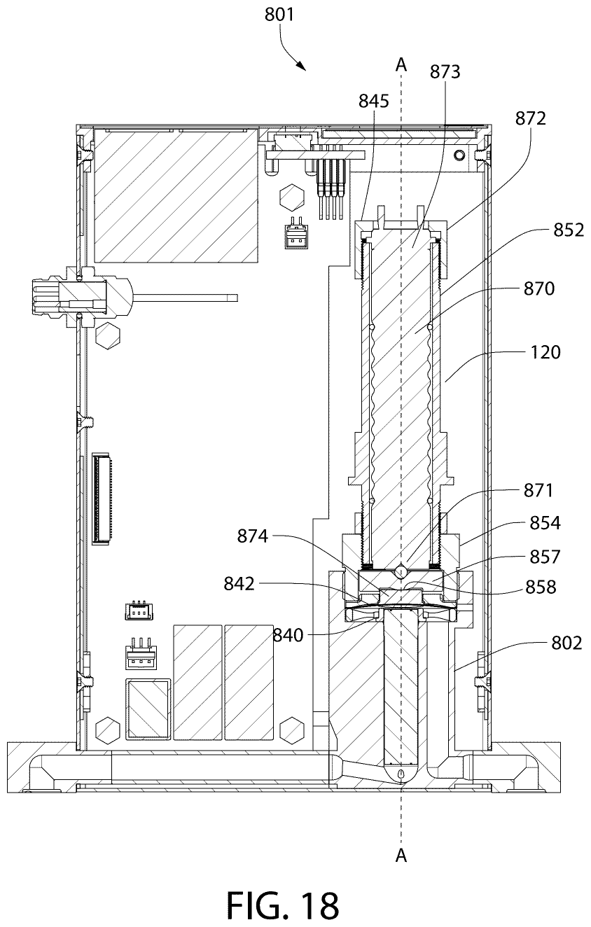

FIG. 18 illustrates another embodiment of the mass flow controller 801. The mass flow controller 801 incorporates a valve 120 mounted on a body 802. The mass flow controller 801 is substantially identical to the mass flow controllers discussed above, except for those features described herein. The valve 120 has an actuator 870 located within a housing 852, the actuator 870 and the housing 852 collectively forming an actuator assembly 845. The housing 852 may surround the actuator 870. The actuator 870 may be a piezoelectric actuator. Optionally, another actuator may be incorporated into the actuator assembly as desired, or the actuator assembly may only utilize a single actuator 870 to operate the valve 120. The valve 120 is a normally open valve, wherein the valve 120 allows fluid flow when the actuator 870 is in an inactive state.

The actuator assembly 845 further comprises a closure member 842 which is biased away from a seat 840. The closure member 842 may be biased out of contact by its own biasing force provided by the shape and structure of the closure member 842. The closure member 842 may be actuated by the actuator 870 via a plunger 857 which in turn operates on a button 874. The plunger 857 may have a protuberance 858 which allows pivoting of the button 874 relative to the plunger 857.

A first end 871 of the actuator 870 engages the plunger 857. When the actuator 870 is placed into an active state by applying a drive voltage, the actuator 870 extends, displacing the plunger 857 and the button 874 toward the seat 840 along a longitudinal axis A-A. The movement of the button 874 reduces a distance between the closure member 842 until it is in contact with the seat 840. At full extension of the actuator 870, there may be a pre-load applied by the actuator 870 to compress the closure member 842 against the seat 840 to place the valve 120 in a closed state. The actuator 870 may also control the distance between the closure member 842 and the seat 840 to control a flow rate through the valve 120.

A second end 873 of the actuator 870 engages a cap element 872 which is threadedly coupled to the housing 852. The force applied by the actuator 870 is transferred through the cap element 872 to the housing 852. The housing 852 is coupled to the base element 854, which is in turn coupled to the body 802. Thus, the housing 852 is substantially fixed with respect to the body 802 and the seat 840. The cap element 872 may be an adjustment means to allow adjustment of the maximum distance between the closure member 842 and the seat 840 and the pre-load applied between the closure member 842 and the seat 840 when the valve 120 is in the closed state.

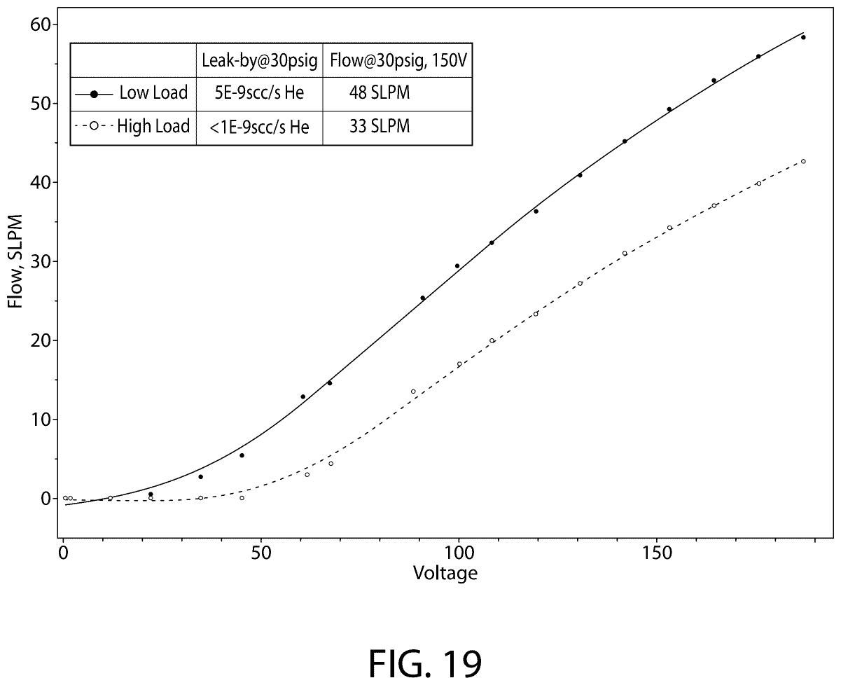

FIG. 19 illustrates experimental test data from the flow controller 701. In the low load scenario, the pre-load between the seat 740 and the closure member 742 is adjusted using the cap element 772 until the leak-by rate at 30 pounds per square inch gauge (“psig”) across the seat 740 of the valve 120 is 5E-9 standard cubic centimeters per second (“scc/s”) of Helium. Flow rates are plotted for a series of drive voltages of the actuator between zero and 200 volts direct current (“DC”). Increasing drive voltage increases the distance between the closure member 742 and the seat 740. At a drive voltage of 150 V DC, the flow rate of Helium is 48 standard liters per minute (“SLPM”) at a supply pressure of 30 psig of Helium.

In another series of data, the cap element 772 is adjusted to achieve a pre-load sufficient to yield a leak-by rate of less than 1E-9 scc/s He at 30 psig across the valve 120. Thus, 30 psig is supplied to the mass flow controller 701 and the outlet of the mass flow controller 701 is coupled to atmosphere. This results in a maximum flow rate of 33 SLPM at a supply pressure of 30 psig of Helium at the same 150 V DC. Thus, by adjusting the flow controller 701 to achieve a reduced pre-load, the leak-by rate may increase, but the maximum flow rate at a given drive voltage similarly increases. In this example, the flow rate increases by 45% when the leak-by rate is adjusted from less than 1E-9 scc/s He at 30 psig supplied to the mass flow controller 701 to 5E-9 scc/s He at 30 psig supplied to the mass flow controller. Where leak-by rates are less critical, maximum flow rates can be increased.

As can be seen from the data in FIG. 19, where the pre-load force is greater, the maximum flow rate at a given drive voltage is reduced. In exchange, the leak-by rates are also reduced. Otherwise stated, where the pre-load force is reduced, the maximum flow rate at a given drive voltage is increased and leak-by rates are increased.

### Exemplary Claim Set

Exemplary claim 1: A system for processing articles comprising: a fluid supply; an apparatus for controlling flow fluidly coupled to the fluid supply, the apparatus for controlling flow comprising: a body comprising a flow path extending from an inlet to an outlet; a valve operably coupled to the flow path between the inlet and the outlet, the valve configured to alter fluid flow within the flow path, the valve comprising a seat and a closure member; a flow restrictor having a flow impedance located within the flow path; and a pressure sensor configured to measure pressure within a volume between the seat of the valve and the flow restrictor; and a processing chamber fluidly coupled to the outlet of the apparatus for controlling flow, the processing chamber configured to process semiconductor devices.

Exemplary claim 2: The system of exemplary claim 1 wherein the valve is located between the inlet and the flow restrictor.

Exemplary claim 3: The system of exemplary claim 1 wherein the valve is located between the flow restrictor and the outlet.

Exemplary claim 4: The system of exemplary claim 1 or exemplary claim 3 further comprising a second pressure sensor configured to measure pressure between the inlet and the flow restrictor.

Exemplary claim 5: The system of any one of exemplary claims 1 to 4 wherein the valve has a leakage rate less than 1E-9 atm cc He/sec at room temperature.

Exemplary claim 6: The system of any one of exemplary claims 1 to 5 wherein the valve is a proportional valve.

Exemplary claim 7: The system of any one of exemplary claims 1 to 6 wherein the valve comprises a first actuator and a second actuator, the first actuator being a pneumatic actuator and the second actuator being a piezoelectric actuator.

Exemplary claim 8: The system of exemplary claim 7 wherein the valve transitions from a closed state where the closure member is in contact with the valve seat to an open state where the closure member is spaced from the valve seat, the valve biased into the closed state by a biasing element.

Exemplary claim 9: The system of exemplary claim 8 wherein the first actuator is configured to transition between an inactive state and an active state, the first actuator applying a first force against the biasing element in the active state.

Exemplary claim 10: The system of exemplary claim 8 or exemplary claim 9 wherein the second actuator is configured to transition between an inactive state and an active state, the first actuator applying a second force against the biasing element in the active state.

Exemplary claim 11: The system of any one of exemplary claims 8 to 10 wherein the valve transitions from the closed state to the open state upon the second actuator being placed in an active state.

Exemplary claim 12: The system of any one of exemplary claims 8 to 11 wherein the valve remains in the closed state when the first actuator is placed in an active state.

Exemplary claim 13: The system of any one of exemplary claims 8 to 11 wherein the valve transitions from the closed state to the open state upon the first actuator being placed in an active state.

Exemplary claim 14: The system of any one of exemplary claims 8 to 13 wherein, in the open state, a distance between the closure member and the valve seat varies based on a drive voltage applied to the second actuator.

Exemplary claim 15: The system of any one of exemplary claims 8 to 14 wherein, in the open state, a distance between the closure member and the valve seat varies based whether the first actuator is in an active state or an inactive state.

Exemplary claim 16: The system of any one of exemplary claims 1 to 15 wherein the apparatus further comprises a first extension extending beyond and fluidly coupled to the body, the inlet formed in the first extension.

Exemplary claim 17: The system of any one of exemplary claims 1 to 6 wherein the valve comprises an actuator, the actuator being a piezoelectric actuator.

Exemplary claim 18: The system of exemplary claim 17 wherein the valve transitions from a closed state where the closure member is in contact with the valve seat to an open state where the closure member is spaced from the valve seat, the valve biased into the closed state by a biasing element.

Exemplary claim 19: The system of exemplary claim 18 wherein the actuator is configured to transition between an inactive state and an active state, the actuator applying a force against the biasing element in the active state.

Exemplary claim 20: The system of exemplary claim 18 or exemplary claim 19 wherein the valve transitions from the closed state to the open state upon the actuator being placed in an active state.

Exemplary claim 21: The system of any one of exemplary claims 18 to 20 wherein, in the open state, a distance between the closure member and the valve seat varies based on a drive voltage applied to the actuator.

Exemplary claim 22: The system of any one of exemplary claims 1 to 6 wherein the valve comprises an actuator, the valve transitioning from an open state where the closure member is spaced from the valve seat to a closed state where the closure member is in contact with the valve seat.

Exemplary claim 23: The system of exemplary claim 22 wherein the actuator is configured to transition between an inactive state and an active state, the actuator applying a force to reduce a distance between the closure member and the valve seat when the actuator is in an active state.

Exemplary claim 24: The system of exemplary claim 23 wherein the distance is maximized when the actuator is in an inactive state.

Exemplary claim 25: The system of any one of exemplary claims 22 to 24 wherein the valve is configured to transition from the open state to the closed state upon the actuator being placed in an active state.

Exemplary claim 26: The system of any one of exemplary claims 22 to 25 wherein, in the active state, a distance between the closure member and the valve seat varies based on a drive voltage applied to the actuator.

Exemplary claim 27: The system of exemplary claim 26 wherein the distance is inversely correlated with the drive voltage.

Exemplary claim 28: The system of any one of exemplary claims 1 to 16 wherein the valve comprises: a button engaging the closure member; a plunger engaging the button; a plurality of transmission pins in contact with the plunger; a piston engaging the plurality of transmission pins; and a biasing element engaging the piston.

Exemplary claim 29: The system of exemplary claim 28 wherein the piston forms a portion of a chamber of a first actuator.

Exemplary claim 30: The system of exemplary claim 28 or exemplary claim 29 wherein a second actuator is concentric with the piston.

Exemplary claim 31: The system of any one of exemplary claims 28 to 30 wherein a second actuator nests within the piston.

Exemplary claim 32: The system of any one of exemplary claims 28 to 31 wherein the biasing element surrounds a second actuator.

Exemplary claim 33: The system of any one of exemplary claims 1 to 16 wherein the valve comprises: a button engaging the closure member; a piston engaging the button; a piezoelectric actuator engaging the piston; and a biasing element engaging the piston.

Exemplary claim 34: The system of exemplary claim 33 wherein the piston forms a portion of a chamber of a first actuator and the piezoelectric actuator is a second actuator.

Exemplary claim 35: The system of exemplary claim 34 wherein transitioning the first actuator from an inactive state to an active state moves the valve from a closed state to an open state.

Exemplary claim 36: The system of exemplary claim 35 wherein, when the second actuator is in an inactive state and the first actuator is in the active state, the valve seat and the closure member are separated by a first distance and when the second actuator is in an active state and the first actuator is in the active state, the valve seat and the closure member are separated by a second distance that is less than the first distance.

Exemplary claim 37: The system of any one of exemplary claims 1 to 36 wherein the apparatus for controlling flow does not utilize a second valve between the inlet and the outlet.

Exemplary claim 38: The system of any one of exemplary claims 1 to 36 wherein the apparatus for controlling flow is a pressure type mass flow controller.

Exemplary claim 39: The system of any one of exemplary claims 1 to 38 wherein the apparatus for controlling flow is configured to transition from a first state where no fluid exits the outlet to a second state where fluid is delivered from the outlet at a substantially constant mass flow rate, a position of the valve driven in an open loop control mode during a transition period between the first and second states.

Exemplary claim 40: The system of exemplary claim 39 wherein the position of the valve is driven in a closed loop control mode subsequent to the transition period.

Exemplary claim 41: The system of exemplary claim 39 or exemplary claim 40 wherein a memory of a controller stores a relationship between the position of the valve and a mass flow rate of fluid at the outlet.

Exemplary claim 42: The system of any one of exemplary claims 39 to 41 wherein the system utilizes feedback from the pressure sensor to control the position of the valve in the second state.

Exemplary claim 43: An apparatus for controlling flow comprising: a body comprising a flow path extending from an inlet to an outlet; a valve operably coupled to the flow path between the inlet and the outlet, the valve configured to alter fluid flow within the flow path, the valve comprising: a seat; a closure member configured to engage the seat; a biasing element biasing the closure member into contact with the seat; a first actuator configured to apply a first force to the biasing element; and a second actuator configured to apply a second force to the biasing element; a flow restrictor having a flow impedance located within the flow path; and a pressure sensor configured to measure pressure within a volume between the seat of the valve and the flow restrictor.

Exemplary claim 44: The apparatus of exemplary claim 43 wherein the first actuator is a pneumatic actuator.

Exemplary claim 45: The apparatus of exemplary claim 43 or exemplary claim 44 wherein the second actuator is one of a piezoelectric actuator, a solenoid, a motor and screw assembly, or a linear motor.

Exemplary claim 46: The apparatus of any one of exemplary claims 43 to 45 wherein the valve is configured to transition from a closed state where the closure member is in contact with the valve seat to an open state where the closure member is spaced from the valve seat, the valve biased into the closed state by the biasing element.

Exemplary claim 47: The apparatus of exemplary claim 46 wherein the first actuator is configured to transition between an inactive state and an active state, the first actuator applying the first force against the biasing element in the active state

Exemplary claim 48: The apparatus of exemplary claim 46 or exemplary claim 47 wherein the second actuator is configured to transition between an inactive state and an active state, the first actuator applying the second force against the biasing element in the active state.

Exemplary claim 49: The apparatus of any one of exemplary claims 46 to 48 wherein the valve transitions from the closed state to the open state upon the second actuator being placed in an active state.

Exemplary claim 50: The apparatus of any one of exemplary claims 46 to 49 wherein the valve remains in the closed state when the first actuator is placed in an active state.

Exemplary claim 51: The apparatus of any one of exemplary claims 46 to 50 wherein the valve transitions from the closed state to the open state upon the first actuator being placed in an active state.

Exemplary claim 52: The apparatus of any one of exemplary claims 46 to 51 wherein, in the open state, a distance between the closure member and the valve seat varies based on a drive voltage applied to the second actuator.

Exemplary claim 53: The apparatus of any one of exemplary claims 46 to 52 wherein, in the open state, a distance between the closure member and the valve seat varies based whether the first actuator is in an active state or an inactive state.

Exemplary claim 54: The apparatus of any one of exemplary claims 43 to 53 wherein the apparatus further comprises a first extension extending beyond and fluidly coupled to the body, the inlet formed in the first extension.

Exemplary claim 55: An apparatus for controlling flow comprising: a body comprising a flow path extending from an inlet to an outlet; a valve operably coupled to the flow path between the inlet and the outlet, the valve configured to alter fluid flow within the flow path, the valve comprising: a seat located within the body; a closure member configured to engage the seat; a biasing element biasing the closure member into contact with the seat; a first actuator configured to apply a first force to the biasing element; and a second actuator configured to apply a second force to the biasing element; a flow restrictor having a flow impedance, the flow restrictor located within the flow path; and a pressure sensor configured to measure pressure within a volume between the seat of the valve and the flow restrictor; wherein the volume is less than 0.1 cubic centimeters.

Exemplary claim 56: The apparatus of exemplary claim 55 wherein the volume is less than 0.01 cubic centimeters.

Exemplary claim 57: The apparatus of exemplary claim 55 or exemplary claim 56 wherein the flow restrictor is located between the seat and the outlet of the flow path.

Exemplary claim 58: The apparatus of any one of exemplary claims 55 to 57 wherein the flow restrictor comprises a sensing channel which fluidly connects the pressure sensor to the volume.

Exemplary claim 59: The apparatus of any one of exemplary claims 55 to 58 further comprising a second pressure sensor configured to measure pressure between the inlet and the flow restrictor.

Exemplary claim 60: The apparatus of any one of exemplary claims 55 to 59 wherein the valve has a leakage less than 1E-9 atm cc He/sec at room temperature.

Exemplary claim 61: The apparatus of any one of exemplary claims 55 to 60 wherein the valve is a proportional valve.

Exemplary claim 62: The apparatus of any one of exemplary claims 55 to 61 wherein the body comprises a cavity configured to receive the valve formed in a first surface, a second surface receiving the pressure sensor and comprising one of the inlet and the outlet, and a third surface comprising the other one of the inlet and the outlet.

Exemplary claim 63: The apparatus of exemplary claim 62 wherein the body comprises a fourth surface receiving a second pressure sensor.

Exemplary claim 64: The apparatus of exemplary claim 62 or exemplary claim 63 further comprising a first extension extending beyond and fluidly coupled to the first surface of the body, the inlet formed in the first extension.

Exemplary claim 65: The apparatus of any one of exemplary claims 55 to 64 wherein the apparatus has no additional valves.

Exemplary claim 66: An apparatus for controlling flow comprising: a body comprising a flow path extending from an inlet to an outlet; a valve operably coupled to the flow path between the inlet and the outlet, the valve configured to alter fluid flow within the flow path, the valve comprising: a seat; a closure member configured to engage the seat; a biasing element biasing the closure member into contact with the seat; and an actuator assembly, the actuator assembly comprising: a button engaging the closure member; a plunger engaging the button; a plurality of transmission pins in contact with the plunger; a piston engaging the plurality of transmission pins; and a biasing element engaging the piston; a flow restrictor having a flow impedance located within the flow path; and a pressure sensor configured to measure pressure within a volume between the seat of the valve and the flow restrictor.

Exemplary claim 67: The apparatus of exemplary claim 66 wherein the piston forms a portion of a chamber of a first actuator.

Exemplary claim 68: The apparatus of exemplary claim 66 or exemplary claim 67 wherein a second actuator is concentric with the piston.

Exemplary claim 69: The apparatus of any one of exemplary claims 66 to 68 wherein a second actuator nests within the piston.

Exemplary claim 70: The apparatus of any one of exemplary claims 66 to 69 wherein the biasing element surrounds a second actuator.

Exemplary claim 71: The apparatus of any one of exemplary claims 66 to 70 wherein the actuator assembly comprises a first actuator and a second actuator, the first actuator applying a first force to the biasing element in an active state and the second actuator applying a second force to the biasing element in an active state.

Exemplary claim 72: The apparatus of exemplary claim 71 wherein the first force is insufficient to separate the closure member from the seat.

Exemplary claim 73: The apparatus of exemplary claim 71 or exemplary claim 72 wherein the second force is sufficient to separate the closure member from the seat.

Exemplary claim 74: The apparatus of any one of exemplary claims 71 to 73 wherein the first and second actuators apply a force against the piston in a direction away from the seat.

Exemplary claim 75: The apparatus of any one of exemplary claims 71 to 74 wherein the actuator assembly further comprises a housing, a base element, and a cap element, the base element rigidly coupled to the body and the housing, the piston configured to move within the housing, and the cap element configured to engage the piston.

Exemplary claim 76: The apparatus of exemplary claim 75 wherein the cap element and the piston collectively enclose the second actuator.

Exemplary claim 77: The apparatus of exemplary claim 75 or exemplary claim 76 wherein the cap element is adjustable relative to the piston.

Exemplary claim 78: An apparatus for controlling flow comprising: a body comprising a flow path extending from an inlet to an outlet; a valve operably coupled to the flow path between the inlet and the outlet, the valve configured to alter fluid flow within the flow path, the valve comprising: a seat; a closure member configured to engage the seat; a biasing element biasing the closure member into contact with the seat; and an actuator assembly, the actuator assembly comprising: a button engaging the closure member; a piston engaging the button, the biasing element engaging the piston; a housing surrounding the piston, the housing and the piston collectively forming a first actuator; and a second actuator engaging the piston; a flow restrictor having a flow impedance within the flow path; and a pressure sensor configured to measure pressure within a volume between the seat of the valve and the flow restrictor.

Exemplary claim 79: The system of exemplary claim 78 wherein the piston and the housing collectively form a chamber of the first actuator.

Exemplary claim 80: The system of exemplary claim 78 or exemplary claim 79 wherein transitioning the first actuator from an inactive state to an active state moves the valve from a closed state to an open state.

Exemplary claim 81: The system of any one of exemplary claims 78 to 80 wherein transitioning the first actuator to an active state causes the first actuator to apply a first force to counteract the biasing element.

Exemplary claim 82: The system of any one of exemplary claims 78 to 81 wherein transitioning the second actuator to an active state causes the second actuator to apply a second force in complement with the biasing element.

Exemplary claim 83: The system of any one of exemplary claims 78 to 82 wherein the biasing element applies a biasing force to the piston, causing the closure member to be biased into contact with the seat.

Exemplary claim 84: The system of any one of exemplary claims 78 to 83 wherein the first actuator compresses the second actuator between the piston and a cap element when the first actuator is in an active state.

Exemplary claim 85: The system of any one of exemplary claims 78 to 84 wherein the second actuator is separated from a cap element by a space when the first actuator is in an inactive state.

Exemplary claim 86: The system of any one of exemplary claims 78 to 85 wherein, when the second actuator is in an inactive state and the first actuator is in an active state, the valve seat and the closure member are separated by a first distance and when the second actuator is in an active state and the first actuator is in the active state, the valve seat and the closure member are separated by a second distance that is less than the first distance.

Exemplary claim 87: A method for processing semiconductors comprising: supplying a fluid to an apparatus for controlling flow, the apparatus for controlling flow comprising a body, a valve, a flow restrictor, and a pressure sensor, the body comprising a flow path extending from an inlet to an outlet, the valve located within the flow path and comprising a seat, a closure member, a biasing element biasing the closure member into contact with the seat, a first actuator configured to control a position of the closure member relative to the seat, and a second actuator configured to control the position of the closure member relative to the seat, the flow restrictor located within the flow path, and the pressure sensor configured to sense a pressure within a volume between the seat of the valve and the flow restrictor, the valve in a closed state preventing the fluid from flowing out of the outlet; receiving a command from a controller to flow the fluid at a predetermined flow rate; transitioning the second actuator to an active state to control the position of the closure member in a first operating mode, the position corresponding to the predetermined flow rate; controlling the second actuator in a second operating mode wherein the second actuator is controlled based on feedback from the pressure sensor.

Exemplary claim 88: The method of exemplary claim 87 wherein, in the step of transitioning, the first operating mode is an open loop control mode.

Exemplary claim 89: The method of exemplary claim 87 or exemplary claim 88 wherein, in the step of transitioning, the predetermined flow rate corresponds to a position setpoint, the position of the valve driven to the position setpoint.

Exemplary claim 90: The method of any one of exemplary claims 87 to 89 wherein, in the step of controlling, the second operating mode is a closed loop control mode.

Exemplary claim 91: The method of any one of exemplary claims 87 to 90 wherein, in the step of transitioning, the first actuator is transitioned to an active state simultaneously with the second actuator being transitioned to the active state.

Exemplary claim 92: The method of any one of exemplary claims 87 to 90 wherein, in the step of transitioning, the first actuator is transitioned to an active state prior to the second actuator being transitioned to the active state.

Exemplary claim 93: The method of exemplary claim 91 or exemplary claim 92 wherein, in the step of transitioning, the first actuator applies a first force against the biasing element and the second actuator applies a second force against the biasing element.

Exemplary claim 94: The method of exemplary claim 93 wherein the first force is insufficient to separate the closure member from the seat.

Exemplary claim 95: A method for processing semiconductors comprising: supplying a fluid to an apparatus for controlling flow, the apparatus for controlling flow comprising a body, a valve, a flow restrictor, and a pressure sensor, the body comprising a flow path extending from an inlet to an outlet, the valve located within the flow path and comprising a seat, a closure member, an actuator configured to control a position of the closure member relative to the seat, the flow restrictor located within the flow path, and the pressure sensor configured to sense a pressure within a volume between the seat of the valve and the flow restrictor, the valve in a closed state preventing the fluid from flowing out of the outlet; receiving a command from a controller to flow the fluid at a predetermined flow rate; transitioning the actuator to an active state to control the position of the closure member in a first operating mode, the position corresponding to the predetermined flow rate; controlling the actuator in a second operating mode wherein the actuator is controlled based on feedback from the pressure sensor.

Exemplary claim 96: The method of exemplary claim 95 wherein, in the step of transitioning, the first operating mode is an open loop control mode.

Exemplary claim 97: The method of exemplary claim 95 or exemplary claim 96 wherein, in the step of transitioning, the predetermined flow rate corresponds to a position setpoint, the position of the valve driven to the position setpoint.

Exemplary claim 98: The method of any one of exemplary claims 95 to 97 wherein, in the step of controlling, the second operating mode is a closed loop control mode.

Exemplary claim 99: The method of any one of exemplary claims 95 to 98 wherein the step of transitioning occurs prior to the step of controlling.

Exemplary claim 100: The method of any one of exemplary claims 95 to 99 wherein the step of transitioning ends when the pressure within the volume stabilizes within a predetermined range.

Exemplary claim 101: The method of exemplary claim 100 wherein the predetermined range is within 5 percent of a target pressure.

Exemplary claim 102: A system for processing articles comprising: a fluid supply; an apparatus for controlling flow fluidly coupled to the fluid supply, the apparatus for controlling flow comprising: a body comprising a flow path extending from an inlet to an outlet; a valve operably coupled to the flow path between the inlet and the outlet, the valve configured to alter fluid flow within the flow path, the valve comprising a seat, a closure member, and an actuator, the valve being normally open when the actuator is in an inactive state; a flow restrictor having a flow impedance located within the flow path; and a pressure sensor configured to measure pressure within a volume between the seat of the valve and the flow restrictor; and a processing chamber fluidly coupled to the outlet of the apparatus for controlling flow, the processing chamber configured to process semiconductor devices.

Exemplary claim 103: The system of exemplary claim 102 wherein the closure member of the valve provides a biasing force which separates the closure member from the seat.

Exemplary claim 104: The system of exemplary claim 102 or exemplary claim 103 wherein the valve is located between the flow restrictor and the outlet.

Exemplary claim 105: The system of any one of exemplary claims 102 to 104 wherein the closure member and the seat are separated by a first distance when the actuator is in an inactive state and the closure member and the seat are separated by a second distance when the actuator is in an active state, the second distance being less than the first distance.

Exemplary claim 106: The system of any one of exemplary claims 102 to 105 further comprising an actuator assembly, the actuator assembly comprising: a button engaging the closure member; a plunger engaging the button; and a housing surrounding the piston, the housing and the piston collectively forming the actuator.

Exemplary claim 107: The system of exemplary claim 106 wherein the actuator is configured to elongate when in an active state, elongation of the actuator configured to reduce a distance between the closure member and the seat.

Exemplary claim 108: The system of exemplary claim 106 or exemplary claim 107 wherein the housing further comprises a cap element, the cap element configured to adjust a position of the actuator relative to the seat.

Exemplary claim 109: An apparatus for controlling flow comprising: a body comprising a flow path extending from an inlet to an outlet; a valve operably coupled to the flow path between the inlet and the outlet, the valve configured to alter fluid flow within the flow path, the valve comprising: a seat; a closure member configured to engage the seat; an actuator configured to control a distance between the closure member and the seat; and an adjustment means configured to adjust a pre-load between the closure member and the seat; a flow restrictor having a flow impedance located within the flow path; and a pressure sensor configured to measure pressure within a volume between the seat of the valve and the flow restrictor; wherein, when the valve is in a closed state, the pre-load is applied to compress the closure member against the seat, the pre-load being adjustable from a first force wherein the apparatus has a first maximum flow rate to a second force wherein the apparatus has a second maximum flow rate, the second force being greater than the first force and the second maximum flow rate being less than the first maximum flow rate.

Exemplary claim 110: The apparatus of exemplary claim 109 wherein the first force corresponds to a leak rate of 5E-9 standard cubic centimeters per second of Helium at 30 pounds per square inch gage pressure across the valve and the second force corresponds to a leak rate of less than 1E-9 standard cubic centimeters per second of Helium at 30 pounds per square inch gage pressure across the valve.

Exemplary claim 111: The apparatus of exemplary claim 109 or exemplary claim 110 wherein the first maximum flow rate is at least 145% of the second maximum flow rate.

Exemplary claim 112: The apparatus of any one of exemplary claims 109 to 111 wherein the first maximum flow rate is 48 standard liters per minute and the second maximum flow rate is 33 standard liters per minute.

Exemplary claim 113: The apparatus of any one of exemplary claims 109 to 112 wherein the actuator is driven at a drive voltage of 150 volts.

Exemplary claim 114: The apparatus of any one of exemplary claims 109 to 113 wherein the actuator is a piezoelectric actuator.

Exemplary claim 115: The apparatus of any one of exemplary claims 109 to 114 wherein a maximum distance between the closure member and the seat is greater for the first force than the second force.

Exemplary claim 116: The apparatus of any one of exemplary claims 109 to 115 wherein the adjustment means is a cap element configured to adjust a position of the actuator relative to the seat.

While the invention has been described with respect to specific examples including presently preferred modes of carrying out the invention, those skilled in the art will appreciate that there are numerous variations and permutations of the above described systems and techniques. It is to be understood that other embodiments may be utilized, and structural and functional modifications may be made without departing from the scope of the present invention. Thus, the spirit and scope of the invention should be construed broadly as set forth in the appended claims.

1. A system for processing articles comprising:
a fluid supply;
an apparatus for controlling flow fluidly coupled to the fluid supply, the apparatus for controlling flow comprising:
a body comprising a flow path extending from an inlet to an outlet;
a valve operably coupled to the flow path between the inlet and the outlet, the valve configured to alter fluid flow within the flow path, the valve comprising a seat and a closure member;
a flow restrictor having a flow impedance located within the flow path; and
a pressure sensor configured to measure pressure within a volume between the seat of the valve and the flow restrictor; and
a processing chamber fluidly coupled to the outlet of the apparatus for controlling flow, the processing chamber configured to process semiconductor devices.

2. The system of claim 1 wherein the valve is located between the inlet and the flow restrictor.

3. The system of claim 1 wherein the valve is located between the flow restrictor and the outlet.

4. (canceled)

5. (canceled)

6. The system of claim 1 wherein the valve is a proportional valve.

7. The system of claim 1 wherein the valve comprises a first actuator and a second actuator, the first actuator being a pneumatic actuator and the second actuator being a piezoelectric actuator; wherein the valve transitions from a closed state where the closure member is in contact with the valve seat to an open state where the closure member is spaced from the valve seat, the valve biased into the closed state by a biasing element; and wherein the first actuator is configured to transition between an inactive state and an active state, the first actuator applying a first force against the biasing element in the active state.

8.-12. (canceled)

13. The system of claim 7 wherein the valve transitions from the closed state to the open state upon the first actuator being placed in an active state.

14. (canceled)

15. The system of claim 7 wherein, in the open state, a distance between the closure member and the valve seat varies based whether the first actuator is in an active state or an inactive state.

16. (canceled)

17. The system of claim 1 wherein the valve comprises an actuator, the actuator being a piezoelectric actuator; wherein the valve transitions from a closed state where the closure member is in contact with the valve seat to an open state where the closure member is spaced from the valve seat, the valve biased into the closed state by a biasing element; and wherein the actuator is configured to transition between an inactive state and an active state, the actuator applying a force against the biasing element in the active state.

18.-21. (canceled)

22. The system of claim 1 wherein the valve comprises an actuator, the valve transitioning from an open state where the closure member is spaced from the valve seat to a closed state where the closure member is in contact with the valve seat; wherein the actuator is configured to transition between an inactive state and an active state, the actuator applying a force to reduce a distance between the closure member and the valve seat when the actuator is in an active state: wherein the distance is maximized when the actuator is in an inactive state; and wherein, in the active state, a distance between the closure member and the valve seat varies based on a drive voltage applied to the actuator.

23.-27. (canceled)

28. The system of claim 1 wherein the valve comprises:
a button engaging the closure member;
a plunger engaging the button;
a plurality of transmission pins in contact with the plunger;
a piston engaging the plurality of transmission pins; and
a biasing element engaging the piston.

29. The system of claim 28 wherein the piston forms a portion of a chamber of a first actuator.

30. (canceled)

31. The system of claim 28 wherein a second actuator nests within the piston.

32. (canceled)

33. The system of claim 1 wherein the valve comprises:
a button engaging the closure member;
a piston engaging the button;
a piezoelectric actuator engaging the piston; and
a biasing element engaging the piston.

34. The system of claim 33 wherein the piston forms a portion of a chamber of a first actuator and the piezoelectric actuator is a second actuator; wherein transitioning the first actuator from an inactive state to an active state moves the valve from a closed state to an open state; and wherein, when the second actuator is in an inactive state and the first actuator is in the active state, the valve seat and the closure member are separated by a first distance and when the second actuator is in an active state and the first actuator is in the active state, the valve seat and the closure member are separated by a second distance that is less than the first distance.

35.-38. (canceled)

39. The system of claim 1 wherein the apparatus for controlling flow is configured to transition from a first state where no fluid exits the outlet to a second state where fluid is delivered from the outlet at a substantially constant mass flow rate, a position of the valve driven in an open loop control mode during a transition period between the first and second states; and wherein the position of the valve is driven in a closed loop control mode subsequent to the transition period.

40.-94. (canceled)

95. A method for processing semiconductors comprising:
supplying a fluid to an apparatus for controlling flow, the apparatus for controlling flow comprising a body, a valve, a flow restrictor, and a pressure sensor, the body comprising a flow path extending from an inlet to an outlet, the valve located within the flow path and comprising a seat, a closure member, an actuator configured to control a position of the closure member relative to the seat, the flow restrictor located within the flow path, and the pressure sensor configured to sense a pressure within a volume between the seat of the valve and the flow restrictor, the valve in a closed state preventing the fluid from flowing out of the outlet;
receiving a command from a controller to flow the fluid at a predetermined flow rate;
transitioning the actuator to an active state to control the position of the closure member in a first operating mode, the position corresponding to the predetermined flow rate;
controlling the actuator in a second operating mode wherein the actuator is controlled based on feedback from the pressure sensor.

96. The method of claim 95 wherein, in the step of transitioning, the first operating mode is an open loop control mode.

97. The method of claim 95 wherein, in the step of transitioning, the predetermined flow rate corresponds to a position setpoint, the position of the valve driven to the position setpoint; and wherein, in the step of controlling, the second operating mode is a closed loop control mode.

98.-108. (canceled)

109. An apparatus for controlling flow comprising:
a body comprising a flow path extending from an inlet to an outlet;
a valve operably coupled to the flow path between the inlet and the outlet, the valve configured to alter fluid flow within the flow path, the valve comprising:
a seat;
a closure member configured to engage the seat;
an actuator configured to control a distance between the closure member and the seat; and
an adjustment means configured to adjust a pre-load between the closure member and the seat;
a flow restrictor having a flow impedance located within the flow path; and
a pressure sensor configured to measure pressure within a volume between the seat of the valve and the flow restrictor;
wherein, when the valve is in a closed state, the pre-load is applied to compress the closure member against the seat, the pre-load being adjustable from a first force wherein the apparatus has a first maximum flow rate to a second force wherein the apparatus has a second maximum flow rate, the second force being greater than the first force and the second maximum flow rate being less than the first maximum flow rate.

110.-114. (canceled)

115. The apparatus of claim 109 wherein a maximum distance between the closure member and the seat is greater for the first force than the second force.

116. (canceled)
